(19) United States
(12) Patent Application Publication
(10) Pub. No.: US 2018/0287568 A1
(43) Pub. Date: Oct. 4, 2018

(54) CALIBRATING A WIRELESS DEVICE FOR DETERMINING POSITIONING USING WIRELESS SIGNALS

(71) Applicant: QUALCOMM Incorporated, San Diego, CA (US)

(72) Inventors: Rahul Malik, San Diego, CA (US); Bo Li, San Diego, CA (US)

(21) Appl. No.: 15/897,073

(22) Filed: Feb. 14, 2018

Related U.S. Application Data
(60) Provisional application No. 62/479,970, filed on Mar. 31, 2017.

(51) Int. Cl. H03F 1/32; H04L 25/02; H03F 3/191

(52) U.S. Cl. CPC H03F 1/3247; H03F 2200/451; H03F 3/191; H04L 25/0206

(57) ABSTRACT

This disclosure provides systems, methods and apparatuses for compensating for differences in path delays and phase offsets between receive paths of a wireless device. In one aspect, a device receives a first wireless signal using first and second receive paths, determines a first channel phase response of the first wireless signal as received by the first receive path, and determines a second channel phase response of the first wireless signal as received by the second receive path. The device compares the first and second channel phase responses with an expected channel phase response, and determines, for each of the first receive path and the second receive path, one or more phase correction values based on the comparison. The device adjusts the first and second channel phase responses based on the phase correction values.

### CROSS-REFERENCE TO RELATED APPLICATIONS

This patent application claims priority to U.S. Provisional Patent Application No. 62/479,970 entitled “CALIBRATING A WIRELESS DEVICE FOR DETERMINING POSITIONING USING WIRELESS SIGNALS” filed on Mar. 31, 2017, assigned to the assignee hereof. The disclosure of the prior application is considered part of and is incorporated by reference in this patent application.

### TECHNICAL FIELD

This disclosure relates generally to wireless networks, and specifically to calibrating a wireless device for estimating angle information of wireless signals.

### DESCRIPTION OF THE RELATED TECHNOLOGY

Angle information such as angle of arrival (AoA) and angle of departure (AoD) information of wireless signals transmitted between devices may be estimated and thereafter used to determine the relative position and orientation between the devices. For example, wireless signals may be received by a first device from a second device, and the first device may use AoA or AoD information of the received wireless signals to determine a line of bearing with respect to the second device.

AoA information of a wireless signal may be estimated based on phase differences of the wireless signal received by multiple antennas of a receiving device, and AoD information of a wireless signal may be estimated based on phase differences of the wireless signal transmitted by multiple antennas of a transmitting device. These phase differences are typically measured by the wireless device's baseband processor, which is coupled to the wireless device's antennas via a plurality of transceiver chains. The antennas, which may be manufactured by an entity different than the manufacturer of the wireless device, are typically coupled to the transceiver chains by a plurality of antenna cables. Differences in antenna cable lengths and differences in operating characteristics between the transceiver chains of the wireless device may cause phase differences measured by the baseband processor to be different from the phase differences of the wireless signal appearing between the antennas, which in turn may reduce the accuracy of angle information estimated by the baseband processor.

### SUMMARY

The systems, methods and devices of this disclosure each have several innovative aspects, no single one of which is solely responsible for the desirable attributes disclosed herein.

One innovative aspect of the subject matter described in this disclosure can be implemented in an apparatus to compensate for differences in path delays and gains between receive paths of the apparatus. In some implementations, the apparatus can receive a first wireless signal using a first receive path and a second receive path. The first receive path can provide components of the first wireless signal received at a first antenna to a baseband processor of the apparatus, and the second receive path can provide components of the first wireless signal received at a second antenna to the baseband processor.

The apparatus can determine a first channel phase response of the first receive path to the first wireless signal, and can determine a second channel phase response of the second receive path to the first wireless signal. The apparatus can compare the first and second channel phase responses with an expected channel phase response, and can determine, for each of the first receive path and the second receive path, one or more phase correction values based on the comparison. In some implementations, at least one of the phase correction values can include a frequency-dependent phase correction value indicating a difference in path delays between the first receive path and the second receive path, and can include a frequency-independent phase correction value indicating a difference in phase offsets between the first receive path and the second receive path.

The apparatus can adjust the first and second channel phase responses based on the phase correction values. In some implementations, the adjusted first and second channel phase responses can compensate for at least one of differences in path delays between the first antenna cable and the second antenna cable, differences in path delays between the first receive chain and the second receive chain, and differences in gain between the first receive chain and the second receive chain. In addition, or in the alternative, the apparatus can estimate angle of arrival information of the first wireless signal based on the adjusted channel phase responses.

Another innovative aspect of the subject matter described in this disclosure can be implemented as a method for compensating for differences in path delays and gains between receive paths of a wireless device. The method can include receiving a first wireless signal using first and second receive paths of the wireless device, determining a first channel phase response of the first receive path to the first wireless signal, determining a second channel phase response of the second receive path to the first wireless signal, and comparing the first and second channel phase responses with an expected channel phase response. The method also can include determining, for each of the first receive path and the second receive path, one or more phase correction values based on the comparison, and adjusting the first and second channel phase responses based on the phase correction values. In addition, or in the alternative, the method can include estimating angle of arrival information of the first wireless signal based on the adjusted channel phase responses.

Another innovative aspect of the subject matter described in this disclosure can be implemented in an apparatus to compensate for differences in path delays and gains between receive paths of the apparatus. In some implementations, the apparatus can receive a wireless signal using a plurality of receive paths, and can select one of the plurality of receive paths as a reference path. The apparatus can determine a first channel phase response of the reference path to the wireless signal, can determine a number of other channel phase responses of a number of corresponding non-selected receive paths to the wireless signal, and can compare the first channel phase response with each of the number of other channel phase responses.

The apparatus can determine a relative path delay and gain difference between the reference path and each of the number of non-selected receive paths based on the comparison, and can determine one or more sets of phase correction values based on the determined relative path delay and gain differences. In some implementations, at least one of the phase correction values can include a frequency-dependent phase correction value indicating a difference in path delays between the reference path and a respective one of the non-selected receive paths, and can include a frequency-independent phase correction value indicating a difference in phase offsets between the reference path and the respective one of the non-selected receive paths.

The apparatus can adjust one or more of the other channel phase responses based on the one or more sets of phase correction values. In some implementations, each of the one or more adjusted channel phase responses can compensate for differences in path delays and gains between the reference path and a corresponding one of the non-selected receive paths. In addition, or in the alternative, the apparatus can estimate angle of arrival information of the wireless signal based on the adjusted channel phase responses.

Another innovative aspect of the subject matter described in this disclosure can be implemented as a method for compensating for differences in path delays and gains between receive paths of a wireless device. In some implementations, the method can include receiving a wireless signal using a plurality of receive paths of the wireless device, each of the receive paths including an antenna cable and a receive chain. The method also can include selecting one of the plurality of receive paths as a reference path; determining a first channel phase response of the reference path to the wireless signal; determining a number of other channel phase responses of a number of corresponding non-selected receive paths to the wireless signal; comparing the first channel phase response with each of the number of other channel phase responses; determining a relative path delay and gain difference between the reference path and each of the number of non-selected receive paths based on the comparison; determining one or more sets of phase correction values based on the determined relative path delay and gain differences; and adjusting one or more of the other channel phase responses based on the one or more sets of phase correction values. In addition, or in the alternative, the method can include estimating angle of arrival information of the wireless signal based on the adjusted channel phase responses.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 shows a block diagram of an example wireless system.

FIG. 2A shows a block diagram of an example wireless device.

FIG. 2B shows a number of antenna cables of the example wireless device of FIG. 2A.

FIG. 3A shows an example test setup for calibrating a receiving device.

FIG. 3B shows the receiving device of FIG. 3A receiving two different wireless signals.

FIG. 4 shows a graph illustrating example measured channel phase responses of a wireless device before calibration.

FIG. 5 shows a graph illustrating example adjusted channel phase responses of the wireless device of FIG. 4 after calibration.

FIG. 6A shows an illustrative flow chart depicting an example operation for compensating for differences in path delays and gains between receive paths of a wireless device.

FIG. 6B shows an illustrative flow chart depicting an example operation for estimating angle information of another wireless signal based on adjusted channel phase responses.

FIG. 7 shows an illustrative flow chart depicting another example operation for compensating for differences in path delays and gains between receive paths of a wireless device.

FIG. 8 shows a graph of example differences in channel phase responses between receive paths of a wireless device.

FIG. 9 shows an illustrative flow chart depicting an example operation for determining one or more phase correction values based on a plurality of wireless signals.

FIG. 10 shows an illustrative flow chart depicting another example operation for estimating angle of arrival information of a wireless signal.

FIG. 11 shows an illustrative flow chart depicting an example operation for estimating angle of departure information of a wireless signal.

FIG. 12 shows an example test setup for calibrating a transmitting device.

FIG. 13 shows an illustrative flow chart depicting an example operation for calibrating a transmitting device.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, system or network that is capable of transmitting and receiving RF signals according to any of the IEEE 16.11 standards, or any of the IEEE 802.11 standards, the Bluetooth® standard, code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless, cellular or internet of things (IOT) network, such as a system utilizing 3G, 4G or 5G, or further implementations thereof, technology.

Angle of arrival information of a wireless signal may be estimated based on phase differences between multiple antennas of a receiving device. For example, a receiving device may use multiple antennas to receive a wireless signal, and then use phase differences between components of the wireless signal arriving at different antennas to estimate angle of arrival information of the wireless signal. Angle of departure information of a wireless signal may be estimated based on phase differences between multiple antennas of the transmitting device. For example, a receiving device may receive a wireless signal transmitted from multiple antennas of a transmitting device, and then use phase differences between the arrivals of signal components transmitted from the different antennas of the transmitting device to estimate angle of departure information of the wireless signal.

The phase differences measured between a wireless device's antennas may be used with (such as combined with) the orientation of the wireless device's antennas to determine angle information of wireless signals. For example, if a receiving device uses two antennas to receive a wireless signal from a transmitting device, and the phase difference between first components of the wireless signal arriving at the first antenna and second components of the wireless signal arriving at the second antenna is zero, then the first and second signal components may be in-phase with each other. Further, if the first signal components arrive at the first antenna at the same time that the second signal components arrive at the second antenna, then it may be inferred that the first and second antennas of the receiving device are equidistant from the transmitting device (and thus the angle of arrival is equal to 0 degrees).

Variations in path delays and gains between different signal paths coupled between the baseband processor and the antennas of a receiving device may cause phase differences of a wireless signal as measured by the baseband processor to be different from the phase differences of the wireless signal appearing between the antennas of the receiving device. Differences or variations between the phase differences measured by the baseband processor and the phase differences appearing between the receiving antennas may reduce the accuracy with which the wireless device can estimate angle information of the wireless signal.

Implementations of the subject matter described in this disclosure may be used to calibrate a receiving device to increase the accuracy with which its baseband processor may estimate angle information (such as angle of arrival information and angle of departure information) of wireless signals received from a transmitting device. In some implementations, the receiving device may include a plurality of antennas coupled to a baseband processor via a plurality of transceiver chains and antenna cables. The transceiver chains may have different signal path delays and different gains resulting, for example, from differences in operating characteristics of circuit components provided within the transceiver chains. The antenna cables may have different signal path delays resulting, for example, from differences in lengths of the antenna cables. As a result, the overall path delay and gain of each of the signal paths between the baseband processor and the antennas may be different from one another. The differences in signal path delays and gains may cause the phase differences measured by the baseband processor to be different from the phase differences appearing between the receiving device's antennas, which in turn may lead to inaccurate estimates of angle information.

In some implementations, the receiving device may determine, for each of its transceiver chains, one or more phase correction values that compensate for differences in signal path delays and gains between the transceiver chain and one or more other transceiver chains of the receiving device. In some implementations, the phase correction values may be based on a comparison between a channel phase response of the transceiver chain and an expected channel phase response of the transceiver chain. In some other implementations, the phase correction values may be based on a comparison between a measured channel phase response of the transceiver chain and a number of measured channel phase responses of a corresponding number of other transceiver chains. The receiving device may apply the phase correction values to one or more of the measured channel phase responses to generate a number of adjusted channel phase responses. The baseband processor may use the adjusted channel phase responses, rather than the measured channel phase responses, to estimate angle information of wireless signals received from the transmitting device.

Implementations of the subject matter described in this disclosure also may be used to calibrate a transmitting device to increase the accuracy with which angle of departure information of wireless signals transmitted from the transmitting device may be estimated by a receiving device. The transmitting device may determine one or more phase correction values for a number of its transmit chains, and may apply the one or more phase correction values to wireless signals prior to transmission to the receiving device. In addition, or in the alternative, the transmitting device may share the one or more determined phase correction values with the receiving device, which may use the received one or more phase correction values when estimating angle of departure information of wireless signals transmitted by the transmitting device.

Particular implementations of the subject matter described in this disclosure can be implemented to realize one or more of the following potential advantages. The ability of a wireless device to adjust the measured or determined channel phase responses of its receive paths to a wireless signal based on phase correction values that account for differences in signal path delays and gains between the receive paths may increase the accuracy with which the baseband processor can estimate angle information of a wireless signal, for example, as compared with angle information estimates that do not account for differences in signal path delays and gains between the receive paths. Additionally, the ability for the wireless device to receive phase correction values indicative of differences in signal path delays and gains between the transmit paths of another wireless device also may increase the accuracy with which the baseband processor can estimate angle information of wireless signals.

As used herein, the term “timing information” may refer to one or more time values that indicate a difference in time between a time of departure (TOD) of one frame or signal from a given device and a time of arrival (TOA) of another frame or signal at the given device, and the term “angle information” may refer to information indicating a direction of one device relative to another device or to information from which the direction of one device relative to another device may be derived. In some implementations, the term “angle information” may refer to angle of arrival (AoA) information and angle of departure (AoD) information.

In addition, as used herein, the term “receive path” refers to a receive chain and an antenna cable coupled between a wireless device's baseband processor and a corresponding one of the wireless device's antennas, the term “transmit path” refers to a transmit chain and an antenna cable coupled between a wireless device's baseband processor and a corresponding one of the wireless device's antennas, the term “path delay” refers to the propagation delay of a corresponding receive path or transmit path of the wireless device, and the term “phase offset” refers to a phase difference of a wireless signal caused by path delays of a corresponding receive path or transmit path of the wireless device. Further, the term “operating characteristics” refers to one or more attributes of circuit components within a transceiver chain that may affect the path delay and gain of the transceiver chain.

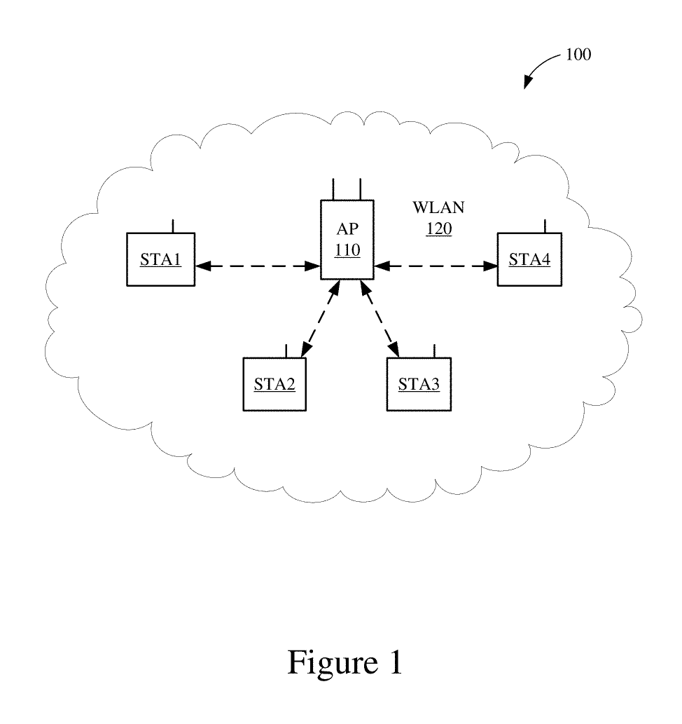

FIG. 1 shows a block diagram of an example wireless system 100. The wireless system 100 is shown to include four wireless stations STA1-STA4, a wireless access point (AP) 110, and a wireless local area network (WLAN) 120. The WLAN 120 may be formed by a plurality of access points (APs) that may operate according to the IEEE 802.11 family of standards (or according to other suitable wireless protocols). Thus, although only one AP 110 is shown in FIG. 1 for simplicity, it is to be understood that the WLAN 120 may be formed by any number of access points such as the AP 110. The AP 110 may be assigned a unique MAC address that is programmed therein by, for example, the manufacturer of the access point. Similarly, each of the stations STA1-STA4 also may be assigned a unique MAC address. Although not specifically shown in FIG. 1, for at least some implementations, the stations STA1-STA4 may exchange signals directly with each other (such as without the presence of the AP 110).

In some implementations, the wireless system 100 may correspond to a multiple-input multiple-output (MIMO) wireless network, and may support single-user MIMO (SU-MIMO) and multi-user (MU-MIMO) communications. Further, although the WLAN 120 is depicted in FIG. 1 as an infrastructure Basic Service Set (BSS), for other implementations, WLAN 120 may be an Independent Basic Service Set (IBSS), an Extended Basic Service Set, an ad-hoc network, or a peer-to-peer (P2P) network (such as operating according to the Wi-Fi Direct protocols).

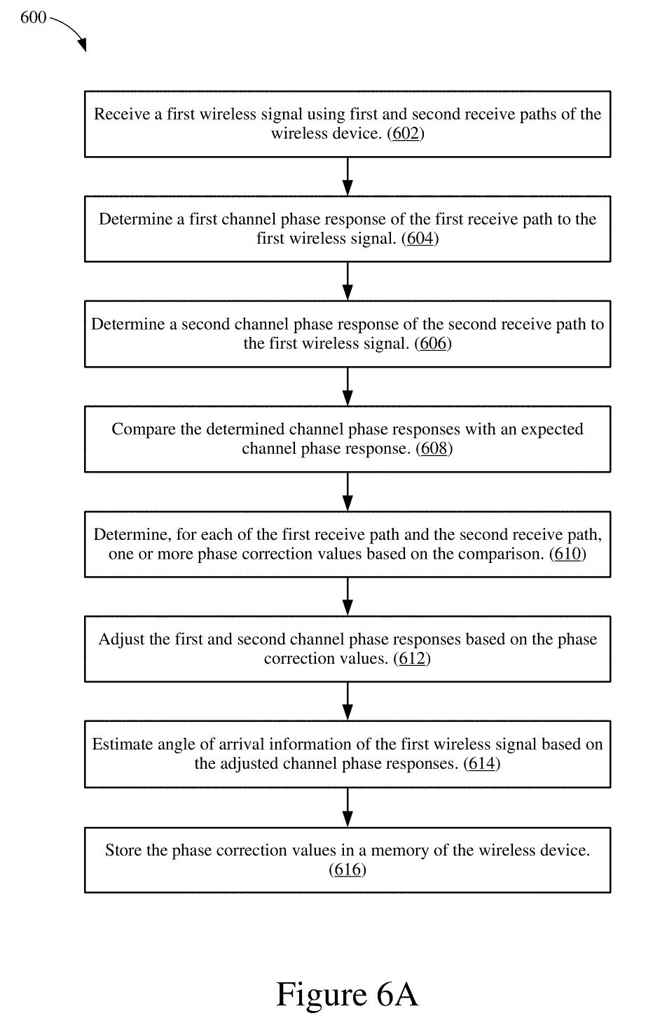

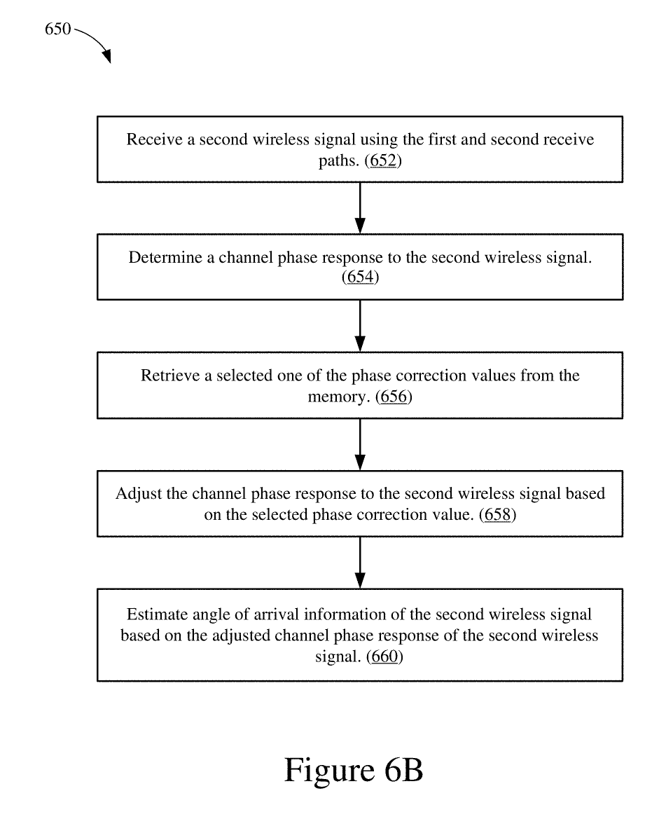

The stations STA1-STA4 may be any suitable Wi-Fi enabled wireless devices including, for example, cell phones, personal digital assistants (PDAs), tablet devices, laptop computers, or the like. The stations STA1-STA4 also may be referred to as a user equipment (UE), a subscriber station, a mobile unit, a subscriber unit, a wireless unit, a remote unit, a mobile device, a wireless device, a wireless communications device, a wireless communication device, a remote device, a mobile subscriber station, an access terminal, a mobile terminal, a wireless terminal, a remote terminal, a handset, a user agent, a mobile client, a client, or some other suitable terminology. For at least some implementations, each of the stations STA1-STA4 may include a transceiver, one or more processing resources (such as processors or ASICs), one or more memory resources, and a power source (such as a battery). The memory resources may include a non-transitory computer-readable medium (such as one or more nonvolatile memory elements, such as EPROM, EEPROM, Flash memory, a hard drive, etc.) that stores instructions for performing operations described below with respect to FIGS. 6A-6B, 7, 9-11, and 13.

The AP 110 may be any suitable device that allows one or more wireless devices to connect to a network (such as a local area network (LAN), wide area network (WAN), metropolitan area network (MAN), or the Internet) via the AP 110 using Wi-Fi, Bluetooth, cellular, or any other suitable wireless communication standards. For at least some implementations, the AP 110 may include a transceiver, a network interface, one or more processing resources, and one or more memory sources. The memory resources may include a non-transitory computer-readable medium (such as one or more nonvolatile memory elements, such as EPROM, EEPROM, Flash memory, a hard drive, etc.) that stores instructions for performing operations described below with respect to FIGS. 6A-6B, 7, 9-11, and 13. In some other implementations, one or more functions of the AP 110 may be performed by one of the stations STA1-STA4 (such as operating as a soft AP).

For the stations STA1-STA4 and the AP 110, the one or more transceivers may include Wi-Fi transceivers, Bluetooth transceivers, cellular transceivers, or other suitable radio frequency (RF) transceivers (not shown for simplicity) to transmit and receive wireless communication signals. Each transceiver may communicate with other wireless devices in distinct frequency bands or using distinct communication protocols. For example, the Wi-Fi transceiver may communicate within a 900 MHz frequency band, within a 2.4 GHz frequency band, within a 5 GHz frequency band, or within a 60 GHz frequency band in accordance with the IEEE 802.11 family of standards. The cellular transceiver may communicate within various RF frequency bands in accordance with the LTE protocol described by the 3rd Generation Partnership Project (3GPP) (such as between approximately 700 MHz and approximately 3.9 GHz) or in accordance with other cellular protocols (such as the GSM protocol). In some implementations, the transceivers included within the stations STA1-STA4 or the AP 110 may be any technically feasible transceiver such as a ZigBee transceiver described by a specification from the ZigBee specification, a WiGig transceiver, or a HomePlug transceiver described by a specification from the HomePlug Alliance.

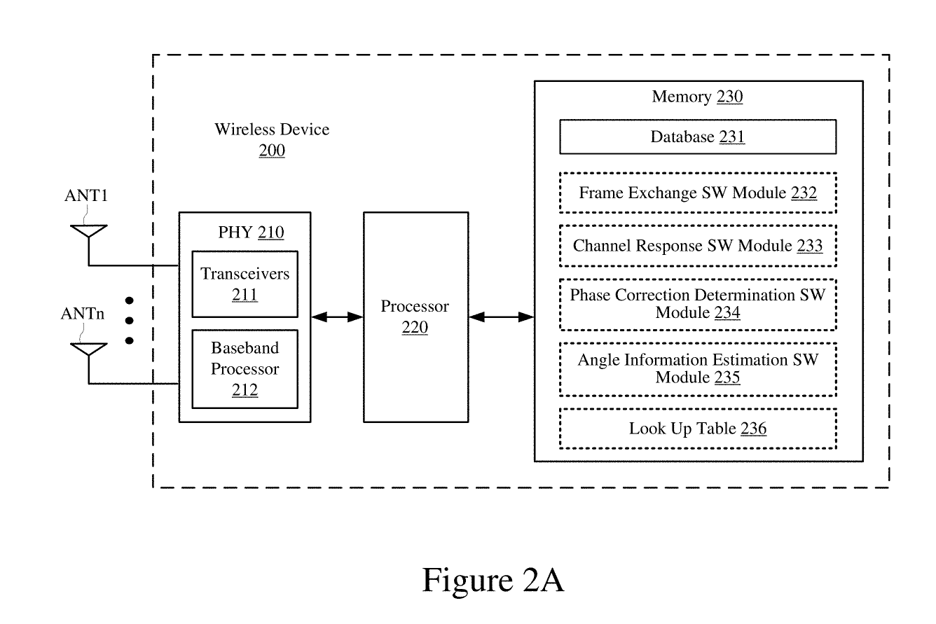

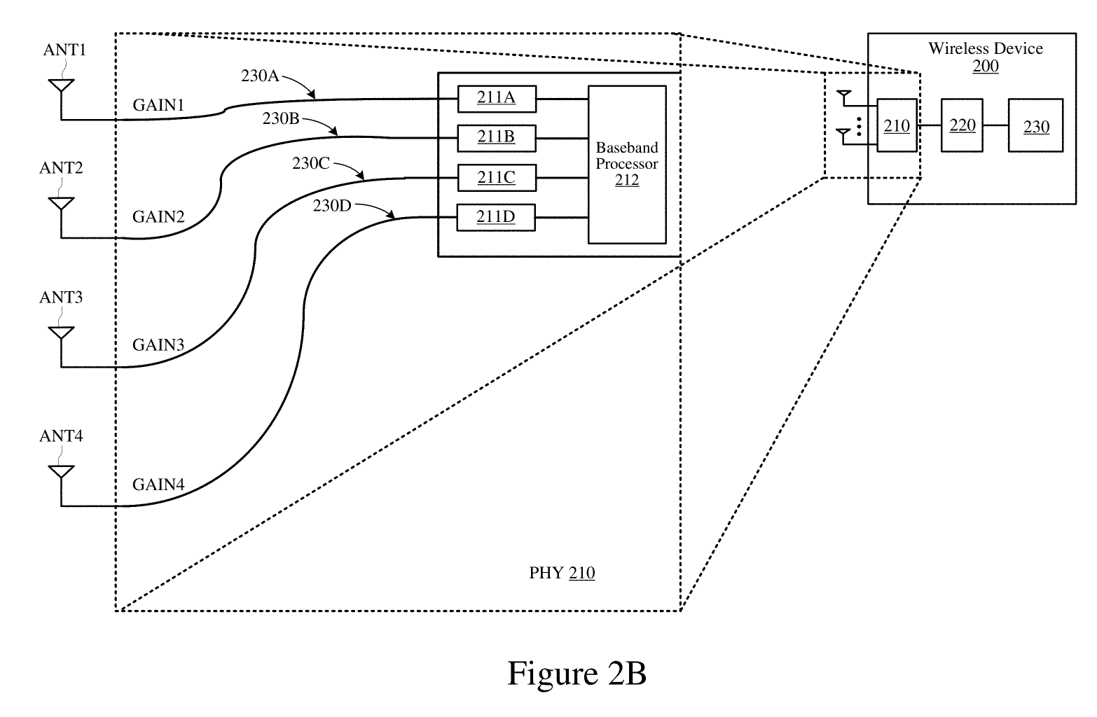

FIG. 2A shows a block diagram of an example wireless device 200. The wireless device 200 may be one implementation of at least one of the stations STA1-STA4 or the AP 110 of FIG. 1. The wireless device 200 may include at least a physical layer device (PHY) 210, a processor 220, a memory 230, and a number of antennas ANT1-ANTn. The PHY 210 may include at least a number of transceivers 211 and a baseband processor 212. The transceivers 211 may be coupled to the antennas ANT1-ANTn via a number of antenna cables (not shown in FIG. 2A for simplicity). In some implementations, the wireless device 200 may include an antenna selection circuit (not shown for simplicity) that can selectively couple the transceivers 211 to different antennas ANT1-ANTn.

The transceivers 211 may be used to transmit signals to and receive signals from other wireless devices including, for example, the AP 110 or one or more of the stations STA1-STA4 of FIG. 1. Although not shown in FIG. 2A for simplicity, the transceivers 211 may include any number of transmit chains to process and transmit signals to other wireless devices via the antennas ANT1-ANTn, and may include any number of receive chains to process signals received from the antennas ANT1-ANTn. Thus, the wireless device 200 may be configured for MIMO operations. The MIMO operations may include SU-MIMO operations and MU-MIMO operations. In some implementations, the wireless device 200 may use multiple antennas ANT1-ANTn to provide antenna diversity. Antenna diversity may include polarization diversity, pattern diversity, and spatial diversity.

The baseband processor 212 may be used to process signals received from the processor 220 and the memory 230 and to forward the processed signals to the transceivers 211 for transmission via one or more of the antennas ANT1-ANTn, and may be used to process signals received from one or more of the antennas ANT1-ANTn via the transceivers 211 and to forward the processed signals to the processor 220 and the memory 230. More specifically, the baseband processor 212, which may be any suitable well-known baseband processor, encodes signals for transmission from the wireless device 200 via the transceivers 211, and decodes signals received from other wireless devices via the transceivers 211.

The transmit chains within the transceivers 211 may include mixers to up-convert signals from a baseband frequency to a carrier frequency for transmission from wireless device 200, and the receive chains within the transceivers 211 may include mixers to down-convert received signals from the carrier frequency to the baseband frequency. Each of the transmit chains also may include a power amplifier, one or more filters, a digital-to-analog converter (DAC), and other well-known components, and each of the receive chains may include a low noise amplifier (LNA), one or more filters, an analog-to-digital converter (ADC), and other well-known components. In some implementations, differences in operating characteristics of these components may cause the transceiver chains to have different path delays, and differences in gain settings of these components may cause the transceiver chains to have different gains.

For purposes of discussion herein, the processor 220 is shown as coupled between the transceivers 211 and the memory 230. In some implementations, the transceivers 211, the processor 220, and the memory 230 may be connected together using one or more buses (not shown for simplicity).

The memory 230 may include a database 231 that may store location data, configuration information, data rates, MAC addresses, timing information, modulation and coding schemes, and other suitable information about (or pertaining to) a number of access points, stations, and other wireless devices. The database 231 also may store profile information for a number of wireless devices. The profile information for a given wireless device may include, for example, the wireless device's service set identification (SSID), channel information, received signal strength indicator (RSSI) values, goodput values, channel state information (CSI), and connection history with the wireless device 200.

The memory 230 also may include a non-transitory computer-readable storage medium (such as one or more nonvolatile memory elements including, for example, EPROM, EEPROM, Flash memory, a hard drive, and so on) that may store the following software (SW) modules:
a frame exchange software module 232 to create and exchange frames (such as data frames, control frames, management frames, or action frames) between the wireless device 200 and other wireless devices, for example, as described with respect to FIGS. 6A-6B, 7, 9-11, and 13;
a channel response software module 233 to determine a channel frequency response of the wireless device 200 to a wireless signal and to determine a channel phase response of each of a number of receive paths or transmit paths of the wireless device 200 to the wireless signal, for example, as described with respect to FIGS. 6A-6B, 7, 9-11, and 13;
a phase correction determination software module 234 to determine one or more phase correction values to compensate for differences in path delays, gains, and phase offsets between the receive paths or the transmit paths of the wireless device 200, for example, as described with respect to FIGS. 6A-6B, 7, 9-11, and 13; and
an angle information estimation software module 235 to estimate angle information of a wireless signal based, at least in part, on the channel phase responses and the one or more phase correction values, for example, as described with respect to FIGS. 6A-6B, 7, 9-11, and 13.

Each software module includes instructions that, when executed by the processor 220, may cause the wireless device 200 to perform the corresponding functions. The non-transitory computer-readable medium of the memory 230 thus includes instructions for performing all or a portion of the operations described below with respect to FIGS. 6A-6B, 7, 9-11, and 13.

The processor 220 may be any one or more suitable processors capable of executing scripts or instructions of one or more software programs stored in the wireless device 200 (such as within the memory 230). For example, the processor 220 may execute the frame exchange software module 232 to create and exchange frames (such as data frames, control frames, management frames, and action frames) between the wireless device 200 and other wireless devices.

The processor 220 may execute the channel response software module 233 to determine a channel frequency response of the wireless device 200 to a wireless signal and to determine a channel phase response of each of a number of receive paths or transmit paths of the wireless device 200. For example, when the wireless device 200 receives a wireless signal, each of the antennas ANT1-ANTn may receive a signal component of the wireless signal, and the various signal components may be provided to the baseband processor 212 via a number of different receive paths of the wireless device 200. Each of the receive paths may include a receive chain (such as within the transceivers 211) and an antenna cable coupled between the baseband processor 212 and a corresponding one of the antennas ANT1-ANT4.

The processor 220 may execute the channel response software module 233 to measure the phase differences between the various signal components of the received wireless signal. In some implementations, the baseband processor 212 may measure the phase differences between a number of signal components of the received wireless signal, for example, as provided to the baseband processor 212 by a corresponding number of the receive paths. The receive paths may have different path delays and different gains resulting from differences in operating characteristics of circuit components provided within the receive paths, differences in gain levels or settings of circuit components provided within the receive paths, and differences in antenna cable lengths.

The processor 220 may execute the phase correction determination software module 234 to determine one or more phase correction values to compensate for differences in path delays, gains, and phase offsets between the receive paths of the wireless device 200. The processor 220 also may execute the phase correction determination software module 234 to determine one or more phase correction values to compensate for differences in path delays, gains, and phase offsets between the transmit paths of the wireless device 200. In some implementations, the one or more phase correction values may be indicative of differences in path delays and phase offsets between a number of the transceiver chains of the wireless device 200. In some other implementations, the one or more phase correction values may be indicative of differences in path delays and phase offsets between a selected transceiver chain of the wireless device 200 and expected path delays and phase offsets, respectively.

The processor 220 may execute the angle information estimation software module 235 to estimate angle information of a wireless signal based, at least in part, on the channel phase responses and the one or more phase correction values. In some implementations, the processor 220 may execute the angle information estimation software module 235 to adjust one or more of the channel phase responses based on the phase correction values, for example, to compensate for variations in path delays, gains, and phase offsets between different receive paths or between different transmit paths of the wireless device 200. The baseband processor 212 may use the adjusted channel phase responses, rather than the determined or measured channel phase responses, to estimate angle information of the received wireless signals.

The memory 230 may include a look-up table 236 that stores a plurality of phase correction values. The look-up table 236 may be indexed by transceiver chain, by gain levels, or by any other suitable indexing scheme. In some implementations, the processor 220, when executing the angle information estimation software module 235, may access the look-up table 236 to retrieve a selected phase correction value for a given one of the receive paths or a given one of the transmit paths (or both) of the wireless device 200. In some other implementations, the processor 220, when executing the angle information estimation software module 235, may access the look-up table 236 to retrieve a selected phase correction value for a given gain level of one or more of the transceiver chains of the wireless device 200. In some other implementations, the phase correction values may be stored in the database 231. In addition, or in the alternative, a transmitting device may provide a number of phase correction values to the wireless device 200 (such as to increase the accuracy with which the wireless device 200 can estimate AoD information of wireless signals transmitted from the transmitting device). In some implementations, the look-up table 236 may store one or more phase correction values for each of a number of other wireless devices.

FIG. 2B shows a number of antenna cables 230A-230D of the example wireless device 200 of FIG. 2A. The antenna cables 230A-230D, which are coupled between corresponding pairs of the antennas ANT1-ANT4 and the transceiver chains 211A-211D of the wireless device 200, may be of different lengths. For the example of FIG. 2B, the first antenna cable 230A is shorter than the second antenna cable 230B, which is shorter than the third antenna cable 230C, which is shorter than the fourth antenna cable 230D. Thus, as measured by the baseband processor 212, the channel frequency response of the first antenna ANT1 may have less phase delay or phase error than the channel frequency response of the second antenna ANT2 (such as because the first antenna cable 230A is shorter than the second antenna cable 230B), the channel frequency response of the second antenna ANT2 may have less phase delay or phase error than the channel frequency response of the third antenna ANT3 (such as because the second antenna cable 230B is shorter than the third antenna cable 230C), and the channel frequency response of the third antenna ANT3 may have less phase delay or phase error than the channel frequency response of the fourth antenna ANT4 (such as because the third antenna cable 230C is shorter than the fourth antenna cable 230D). Additionally, the receive gains GAIN1-GAIN4 associated with respective antennas ANT1-ANT4 may be different from each other, which also may cause differences in channel frequency responses between the signal paths of the wireless device 200, for example, as determined by the baseband processor 212.

The orientation of a wireless device's antennas, the gain levels of the antennas, and the lengths of its antenna cables do not typically change over time. Thus, phase errors resulting from differences in antenna cable lengths in a wireless device may remain constant over time. In some implementations, a wireless device may measure the phase errors caused by different gains and different antenna cable lengths in one or more test cases, and may use the measured phase errors to determine one or more phase correction values for each of a number of its signal paths. The wireless device may use the determined phase correction values to compensate for differences in path delays and gains between its signal paths, for example, when estimating angle information of wireless signals.

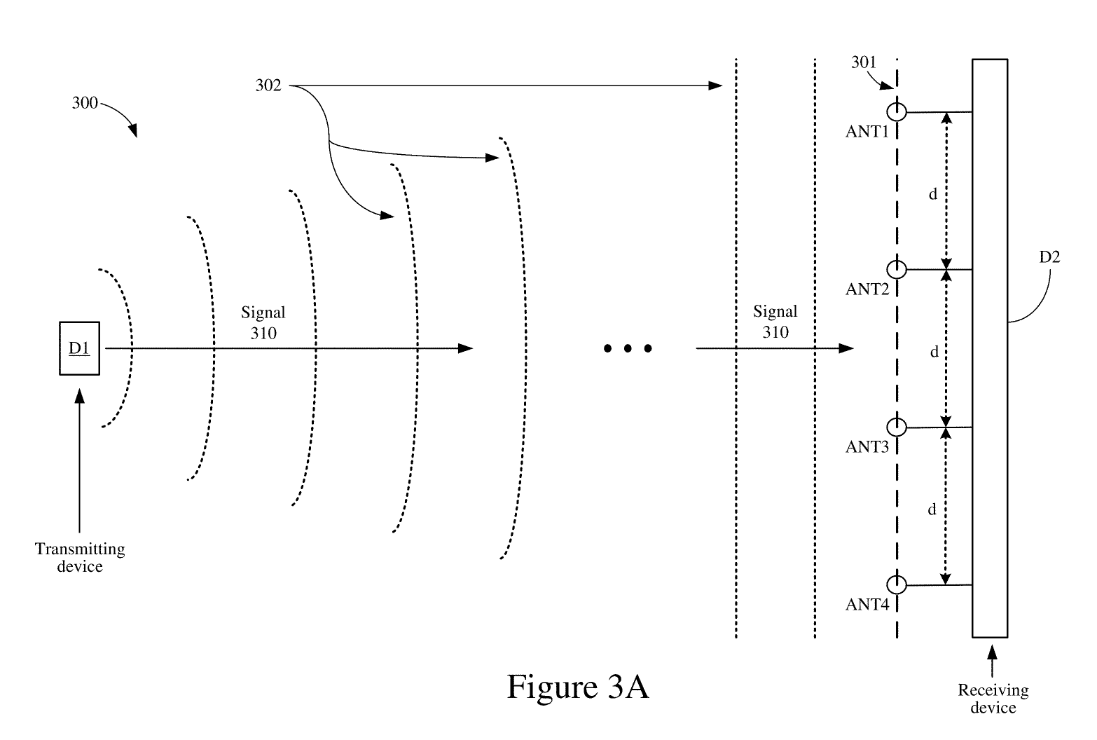

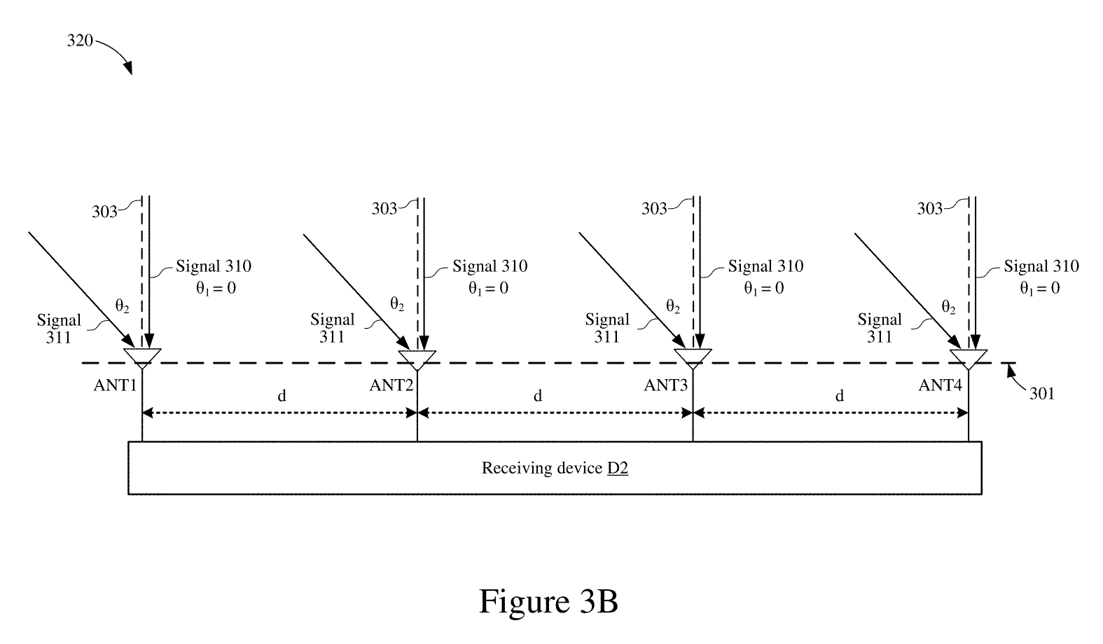

FIG. 3A shows an example test setup 300 for calibrating a receiving device. The test setup 300 is shown to include a transmitting device D1 and a receiving device D2, and may be used to calibrate the receiving device D2 to improve the accuracy with which the receiving device D2 can estimate angle information of received wireless signals. The receiving device D2, which includes four antennas ANT1-ANT4 oriented along a straight line 301 and separated from each other by a distance d, is depicted as receiving a wireless signal 310 that is transmitted from the transmitting device D1. In some implementations, the test setup 300 may be used by a device manufacturer (such as during assembly of the receiving device D2) to calibrate the receiving device D2 prior to being made available for public sale. In some other implementations, the test setup 300 may be used by a component manufacturer (such as in a factory) to calibrate the PHY 210 of FIG. 2A prior to assembly of the receiving device D2.

In some implementations, the test setup 300 may be performed in an anechoic chamber, for example, so that the receiving device D2 does not receive reflections of the wireless signal 310 (such as being reflected off of walls or other objects), but instead receives only line of sight (LOS) signal components of the wireless signal 310. In some other implementations, the receiving device D2 may receive both non-line of sight (NLOS) signal components and LOS signal components of the wireless signal 310, and may filter out or otherwise remove the NLOS signal components, for example, so that only the LOS signal components of the wireless signal 310 are used to estimate angle information of the received wireless signal.

In some implementations, the receiving device D2 may be positioned a sufficient distance from the transmitting device D1 so that the wireless signal 310 reaches the receiving device D2 in the approximate form of a plane wave (such as indicated by plane waves 302). The transmitting device D1 and the receiving device D2 also may be positioned or oriented relative to each other so that the wireless signal 310 arrives at each of the antennas ANT1-ANT4 of the receiving device D2 at the same time (or at least at substantially similar times), for example, so that the wireless signal 310 has an AoA=0 degrees. In this manner, the channel frequency responses of the antennas ANT1-ANT4 can be measured over a known channel at a known position with respect to the transmitting device D1. In some other implementations, the transmitting device D1 and the receiving device D2 may have other orientations relative to each other, for example, as long as the angle information (such as the AoA) of wireless signal 310 is known to the receiving device D2.

Knowing the angle information (such as the AoA) of the wireless signal 310 may allow the receiving device D2 to determine an expected channel phase response of the wireless signal 310. More specifically, if the angle information of the wireless signal 310 is known to the receiving device D2, then the antennas ANT1-ANT4 of the receiving device D2 may each have an expected channel phase response to the wireless signal 310. The receiving device D2 may determine one or more phase correction values for a number of its receive paths based on a comparison between the measured channel phase responses of the antennas ANT1-ANT4 and the expected channel phase responses of the antennas ANT1-ANT4. The receiving device D2 may calibrate itself using the determined phase correction values to compensate for differences in path delays, differences in phase offsets, and differences in gains between its receive paths. In some implementations, the receiving device D2 may determine one or more phase correction values for each of its receive paths (such as for different gain levels). In some other implementations, the receiving device D2 may determine one or more phase correction values for a selected number of its receive paths.

In some other implementations, an end-user may employ aspects of the present disclosure to calibrate the receiving device D2. In some implementations, a user may calibrate an access point (AP) in his home or office using a smartphone. In some implementations, the smartphone may include an application that, when executed by one or more processors of the smartphone, allows the user to position the smartphone at a known orientation relative to the AP. The smartphone may transmit wireless signals to the AP, and the AP may use the received wireless signals to determine channel phase responses at a plurality of its antennas. Because the smartphone has a known orientation relative to the AP, the angle information of wireless signals received from the smartphone may be known, which may allow the AP to determine expected channel phase response. The AP may determine one or more phase correction values based on a comparison between the measured channel phase responses and the expected channel phase responses, and thereafter calibrate itself using the one or more phase correction values.

FIG. 3B shows the receiving device D2 of FIG. 3A receiving two different wireless signals 310 and 311. As shown in the illustration 320 of FIG. 3B, the first wireless signal 310 arrives at each of the antennas ANT1-ANT4 of the receiving device D2 at the same time along a line of direction 303 that is perpendicular to the line 301 along which the antennas ANT1-ANT4 are oriented. Therefore, the angle of arrival θ₁ of the first wireless signal 310 is expected to be zero (θ₁=0), and the channel phase responses associated with each of the receive chains of the receiving device D2 should be equal to one another.

The second wireless signal 311 arrives at the receiving device D2 at a non-zero angle of arrival (02). As depicted in FIG. 3B, the second wireless signal 311 travels farther to reach the fourth antenna ANT4 than to reach the third antenna ANT3, travels farther to reach the third antenna ANT3 than to reach the second antenna ANT2, and travels farther to reach the second antenna ANT2 than to reach the first antenna ANT1. Because the first and second antennas ANT1 and ANT2 are separated by a distance d, the second wireless signal 311 as received by the second antenna ANT2 travels a distance D longer than the second wireless signal 311 as received by the first antenna ANT1, for example, as may be expressed by EQ. 1 below:

D=d*cos(90°−θ₂). (EQ. 1)

Similarly, the second wireless signal 311 travels a distance D longer to reach the third antenna ANT3 than to reach the second antenna ANT2, and travels a distance D longer to reach the fourth antenna ANT4 than to reach the third antenna ANT3. If there are no differences in path delays and gains between the receive paths of the receiving device D2 (such as the antenna cable lengths associated with antennas ANT1-ANT4 are the same and each of the corresponding receive chains has the same operating characteristics), then the phase differences between signal components of the second wireless signal 311 arriving at different ones of the four antennas ANT1-ANT4 of the receiving device D2 may be used to determine the distance D, which in turn may be used to determine or derive the angle of arrival of the second wireless signal 311.

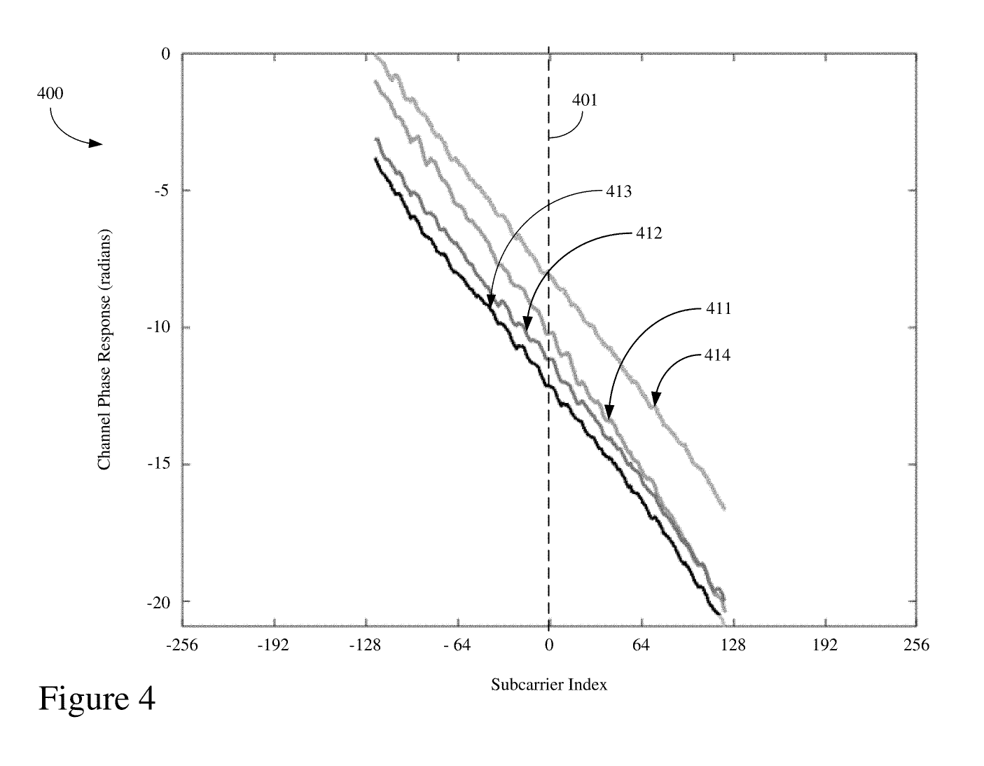

FIG. 4 shows a graph 400 illustrating example measured channel phase responses 411-414 of a wireless device before calibration. The measured channel phase responses 411-414 may correspond to the four antennas ANT1-ANT4, respectively, of a wireless device before its calibration. In some implementations, the wireless device may be the wireless device 200 of FIGS. 2A and 2B. In some other implementations, the wireless device may be the receiving device D2 of FIGS. 3A and 3B. The channel phase responses 411-414 are expressed in radians as a function of the channel's subcarrier indices, and were measured in an anechoic chamber (such as the test setup 300 described with respect to FIG. 3A) so that the wireless device does not receive signal reflections (such as multipath signals). Because the antennas ANT1-ANT4 do not receive signal reflections in an anechoic chamber, the unwrapped channel phase responses 411-414 of the antennas ANT1-ANT4 may be approximated as straight lines. For each of the channel phase responses 411-414, the slope is indicative of the path delay of a corresponding signal path of the wireless device, and the y-intercept point 401 is indicative of the phase offset of the corresponding signal path. For the example of FIG. 4, the y-intercept point of each of the channel phase responses 411-414 is defined as the magnitude of the corresponding line for a Subcarrier Index=0. It is noted that because the antennas ANT1-ANT4 are synchronized with each other, the Sample Time Offset may be constant across the antennas ANT1-ANT4.

If the receive paths have the same (or similar) path delays, then the channel phase responses 411-414 of the graph 400 should have the same slope. For example, as depicted in the graph 400, the slopes of channel phase responses 412-414 (corresponding to signal components of the wireless signal received at antennas ANT2-ANT4, respectively) are the same (or similar to each other), which may indicate that the path delays of the receive paths associated with antennas ANT2-ANT4 are similar to each other. Conversely, the slope of channel phase response 411 (corresponding to signal components of the wireless signal received at antenna ANT1) is different than the slopes of channel phase responses 412-414, which may indicate that the path delay of the receive path associated with antenna ANT1 is different than the path delays of the receive paths associated with antennas ANT2-ANT4. Differences in slopes of the channel phase responses 411-414 may not only indicate differences in phase offsets between the various receive paths coupled between the baseband processor and the antennas ANT1-ANT4, but also may be used to determine one or more phase correction values for calibrating the wireless device.

In some implementations, one of the receive chains of the wireless device may be selected as a reference chain, and the measured channel phase response of the reference chain may be compared with the measured channel phase responses of the other non-selected (or non-reference) receive chains. The results of the comparison may be used to determine one or more phase correction values for each of the non-selected receive chains of the wireless device (such that the phase correction values for the non-selected receive chains are determined with respect to the reference chain). For example, also referring to FIG. 3B, if the first receive chain of the receiving device D2 is selected as the reference chain, the measured channel phase response of the first receive chain may be used as a reference channel phase response and compared with the measured channel phase responses of the non-selected receive chains. The results of the comparison between the measured channel phase response of the reference chain and the measured channel phase responses of the other non-selected receive chains may be used to determine one or more phase correction values for the each of the non-selected receive chains of the receiving device D2. The determined phase correction values may be used to adjust the channel phase responses of one or more of the non-selected receive chains to compensate for differences in path delays and differences in gains between the receive chains of the receiving device D2. The baseband processor may use the adjusted channel phase responses, rather than the measured channel phase responses, to estimate angle information of received wireless signals.

The phase correction value for a respective receive chain (such as for a given gain level or setting) may include a frequency-dependent phase correction value and a frequency-independent phase correction value. The frequency-dependent phase correction value may be used to compensate for differences in path delays between the receive paths of a wireless device, and the frequency-independent phase correction value may be used to compensate for differences in phase offsets between the receive paths of a wireless device. Referring also to the graph 400 of FIG. 4, the frequency-dependent phase correction value may be used to adjust the slopes of one or more of the channel phase responses 411-414 corresponding to the non-selected receive chains to match the slope of the channel phase response corresponding to the reference chain. After the frequency-dependent phase correction values are applied to the channel phase responses corresponding to one or more of the non-selected receive chains, the channel phase responses 411-414 of all four antennas ANT1-ANT4 may have the same slope across a frequency range (such as a channel's subcarriers).

Although the channel phase responses 411-414 may have the same slope after applying the frequency-dependent phase correction values to compensate for differences in path delays between the receive paths, the channel phase responses 411-414 may have different y-intercept points. Differences in the y-intercept points of the channel phase responses 411-414 may indicate different phase offsets between the receive paths of the wireless device caused, for example, by variations in operating characteristics of circuit components provided within the corresponding receive chains. In some implementations, the frequency-independent phase correction values may be used to compensate for these differences in phase offsets. In some implementations, the reference chain may be used to determine one or more frequency-independent phase correction values for the non-selected receive chains, and the one or more frequency-independent phase correction values may be used to adjust one or more of the channel phase responses corresponding to the non-selected receive chains, for example, so that the y-intercept points of the channel phase responses 411-414 match each other (such as being approximately equal to each other).

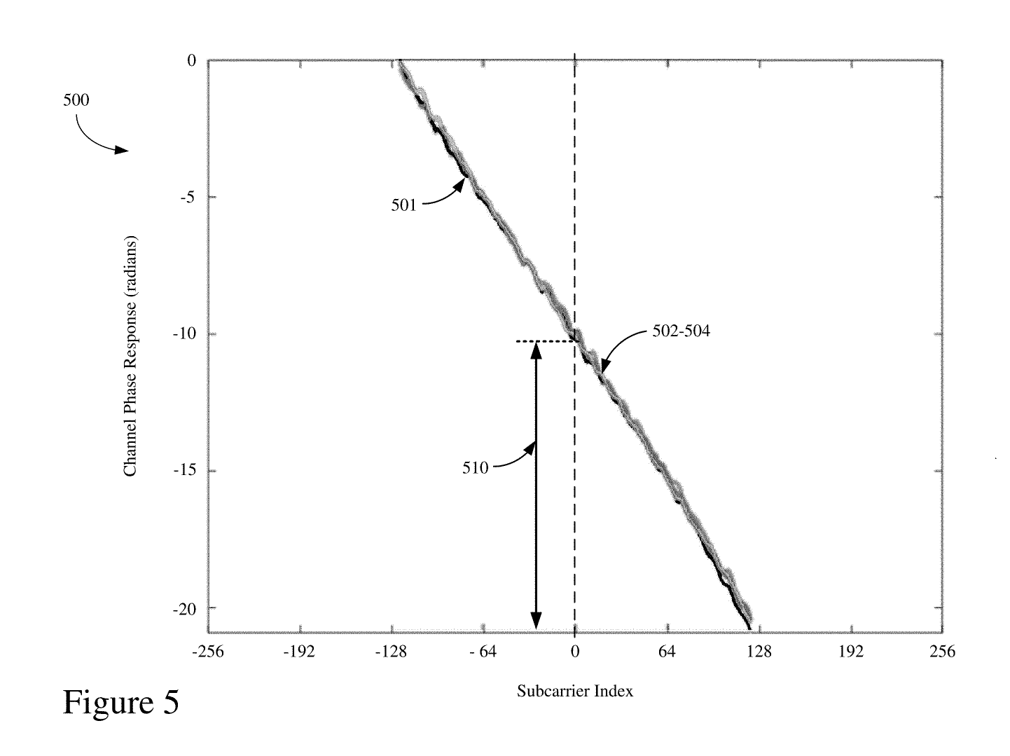

FIG. 5 shows a graph 500 illustrating example adjusted channel phase responses 501-504 of the wireless device of FIG. 4 after calibration. The adjusted channel phase responses 501-504 are expressed in radians as a function of the channel's subcarrier indices. For the example of FIG. 5, the receive chain associated with antenna ANT1 is selected as the reference chain, and the receive chains associated with antennas ANT2-ANT4 are designated as the non-selected receive chains. The channel phase responses 502-504 corresponding to the non-selected receive chains have been adjusted, for example, so that each of the channel phase responses 502-504 corresponding to the non-selected receive chains has the same slope and the same y-intercept point as the channel phase response 501 corresponding to the reference chain. The distance of the channel phase response 501 along the y-axis for subcarrier index values greater than zero (0), as indicated by an arrow 510, may represent the phase correction value for the first receive path of the wireless device. Similarly, the distances of the channel phase responses 502-504 along the y-axis for subcarrier index values greater than 0 may represent the phase correction values for the second, third, and fourth receive paths, respectively, of the wireless device.

FIG. 6A shows an illustrative flow chart depicting an example operation 600 for compensating for differences in path delays and gains between receive paths of a wireless device. Although described with respect to the wireless device 200 of FIGS. 2A and 2B, the example operation 600 may be performed by any suitable wireless device including, for example, one of the stations STA1-STA4 or the AP 110 of FIG. 1. Further, although described in the context of using two antennas (such as the first and second antennas ANT1-ANT2) of the wireless device 200 to receive wireless signals, the example operation 600 is equally applicable when the wireless device 200 uses more than two antennas to receive wireless signals (such as when using four antennas ANT1-ANT4 of the wireless device 200 to receive wireless signals).

The wireless device 200 may receive a first wireless signal using its first and second receive paths (602). Referring also to FIGS. 2A-2B and FIGS. 3A-3B, a first wireless signal 310 may be received at the first and second antennas ANT1-ANT2 of the wireless device 200. Signal components of the first wireless signal 310 received by the first antenna ANT1 may be provided to the baseband processor 220 by the first receive path, and signal components of the first wireless signal 310 received by the second antenna ANT2 may be provided to the baseband processor 220 by the second receive path. The first receive path may include the first antenna cable 230A and the first receive chain 211A, and the second receive path may include the second antenna cable 230B and the second receive chain 211B.

The wireless device 200 may determine a first channel phase response of the first receive path to the first wireless signal (604), and may determine a second channel phase response of the second receive path to the first wireless signal (606).

The wireless device 200 may compare the first and second channel phase responses with an expected channel phase response (608). In some implementations, the wireless device 200 may use the test setup 300 described with respect to FIG. 3A (or any other suitable anechoic chamber) to obtain or otherwise determine the expected channel phase response. For example, referring to the test setup 300 of FIG. 3A, the wireless device 200 may be the receiving device D2, may receive the first wireless signal 310 from the transmitting device D1, and may determine the channel phase response of the first antenna ANT1 in the manner described with respect to FIG. 3A. In some implementations, the first channel phase response may be derived from the channel frequency response of the first antenna ANT1.

The wireless device 200 may determine, for each of the first receive path and the second receive path, one or more phase correction values based on the comparison (610). In some implementations, at least one of the phase correction values may include a frequency-dependent phase correction value and a frequency-independent phase correction value. The frequency-dependent phase correction value may indicate a difference in path delays between the first receive path and the second receive path, and the frequency-independent phase correction value may indicate a difference in phase offsets between the first receive path and the second receive path.

In some implementations, a first frequency-dependent phase correction value may be used to compensate for a difference between the path delay of the first receive path and an expected path delay, and a second frequency-dependent phase correction value may be used to compensate for a difference between the path delay of the second receive path and the expected path delay. In some implementations, a first frequency-independent phase correction value may be used to compensate for a difference between the phase offset of the first receive path and an expected phase offset, and a second frequency-independent phase correction value may be used to compensate for a difference between the phase offset of the second receive path and the expected phase offset. In some implementations, the first frequency-dependent phase correction value may be used to adjust the slope of the channel phase response of the first antenna ANT1 (as described with respect to FIG. 4), and the first frequency-independent phase correction value may be used to adjust the y-intercept point of the channel phase response of the first antenna ANT1 (as described with respect to FIG. 5). Similarly, the second frequency-dependent phase correction value may be used to adjust the slope of the channel phase response of the second antenna ANT2 (as described with respect to FIG. 4), and the second frequency-independent phase correction value may be used to adjust the y-intercept point of the channel phase response of the second antenna ANT2 (as described with respect to FIG. 5).

The wireless device 200 may adjust the first and second channel phase responses based on the phase correction values (612). In some implementations, the wireless device 200 may generate adjusted channel phase responses by applying selected phase correction values to the determined channel phase responses. The adjusted channel phase responses may compensate for differences in path delays, gains, and phase offsets between the first and second receive paths of the wireless device 200.

The wireless device 200 may estimate angle of arrival information of the first wireless signal based on the adjusted channel phase responses (614). Estimating angle information of the first wireless signal based on the adjusted channel phase responses may increase the accuracy with which the wireless device 200 can estimate angle information (such as compared with conventional devices that do not adjust channel phase responses measured by the baseband processor), for example, because the adjusted channel phase responses account for differences in path delays and gains between the receive chains of the wireless device 200.

The wireless device 200 may store the determined phase correction values in a memory (616). In some implementations, the determined phase correction values may be stored in the look-up table 236 of FIG. 2A. In some other implementations, the determined phase correction values may be stored in another suitable memory of the wireless device 200.

The operation 600 may be repeated for different gains of the receive chains of the wireless device 200. In some implementations, the wireless device 200 may determine, for each of a number of gain settings of the first receive path, a phase correction value that may compensate for phase offsets associated with the first receive path. One of the determined phase correction values may be selected based on the gain settings of the first receive path when receiving wireless signals. The selected phase correction value may be applied to the determined channel phase response, for example, to generate an adjusted channel phase response that matches the expected channel phase response.

FIG. 6B shows an illustrative flow chart depicting an example operation 650 for estimating angle information of another wireless signal based on adjusted channel phase responses. Although described with respect to the wireless device 200 of FIGS. 2A and 2B, the example operation 650 may be performed by any suitable wireless device including, for example, one of the stations STA1-STA4 or the AP 110 of FIG. 1. Further, although described in the context of using two antennas (such as the first and second antennas ANT1-ANT2) of the wireless device 200 to receive wireless signals, the example operation 650 is equally applicable when the wireless device 200 uses more than two antennas to receive wireless signals (such as when using four antennas ANT1-ANT4 of the wireless device 200 to receive wireless signals).

The wireless device 200 may receive a second wireless signal using the first and second receive paths (652). Referring also to FIGS. 2A-2B and FIGS. 3A-3B, a second wireless signal 311 may be received at the first and second antennas ANT1-ANT2 of the wireless device 200. Signal components of the second wireless signal 311 received by the first antenna ANT1 may be provided to the baseband processor 220 by the first receive path, and signal components of the second wireless signal 311 received by the second antenna ANT2 may be provided to the baseband processor 220 by the second receive path.

The wireless device 200 may determine a channel phase response to the second wireless signal (654) and may retrieve a selected one of the phase correction values from the memory (656). In some implementations, the phase correction values may be determined and stored in memory of the wireless device 200 during the example operation 600 of FIG. 6A. The selection of the phase correction value to be retrieved from memory may be based on a given gain level of the first receive path, an identification of the second receive path, or a combination thereof.

The wireless device 200 may adjust the channel phase response to the second wireless signal based on the selected phase correction value (658). In some implementations, the adjusted channel phase response may be determined by applying the selected phase correction value to the determined channel phase response to the second wireless signal, for example, to compensate for differences in path delays and differences in gains between the receive chains of the wireless device 200.

The wireless device 200 may estimate angle of arrival information of the second wireless signal based on the adjusted channel phase response to the second wireless signal (660). Estimating angle information of the wireless signal based on the adjusted channel phase responses may increase the accuracy with which the wireless device 200 can estimate angle information (such as compared with conventional devices that do not adjust channel phase responses measured by the baseband processor), for example, because the adjusted channel phase responses account for differences in path delays and gains between the receive chains of the wireless device 200.

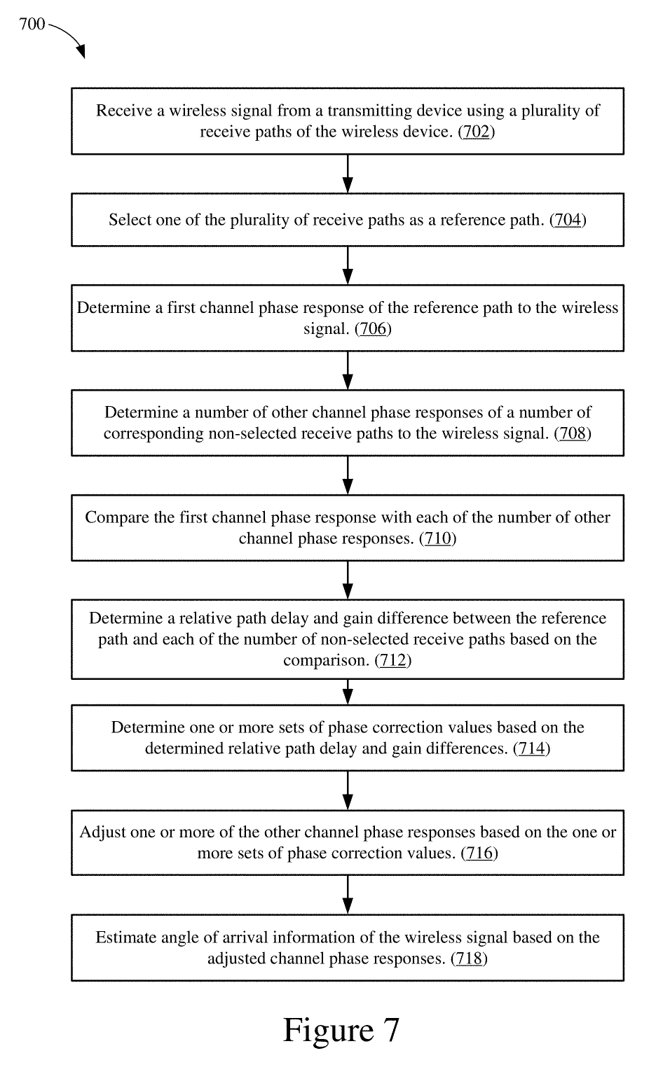

FIG. 7 shows an illustrative flow chart depicting another example operation 700 for compensating for differences in path delays and gains between receive paths of a wireless device. Although described with respect to the wireless device 200 of FIGS. 2A and 2B, the example operation 700 may be performed by any suitable wireless device including, for example, one of the stations STA1-STA4 or the AP 110 of FIG. 1. In some implementations, the operation 700 may be repeated for different gains of the receive paths of the wireless device 200. In some other implementations, the operation 700 may be repeated by selecting different receive chains as the reference chain of the wireless device 200. Further, although described in the context of using two antennas (such as the first and second antennas ANT1-ANT2) of the wireless device 200 to receive wireless signals, the example operation 700 is equally applicable when the wireless device 200 uses more than two antennas to receive wireless signals (such as when using four antennas ANT1-ANT4 of the wireless device 200 to receive wireless signals).

The wireless device 200 may receive a wireless signal from a transmitting device using a plurality of its receive paths (702). Signal components of the wireless signal may be received by each of the antennas ANT1-ANT4 and provided to the baseband processor 220 via corresponding pairs of the antenna cables 230A-230D and receive chains provided within the transceivers 211A-211D.

The wireless device 200 may select one of its plurality of receive paths as a reference path (704). For the example operation 700, the first receive path may be selected as the reference path, and the other receive paths may be designated as non-selected (or non-reference) receive paths. In some other implementations, one of the other receive paths of the wireless device 200 may be selected as the reference path.

The wireless device 200 may determine a first channel phase response of the reference path to the wireless signal (706), and may determine a number of other channel phase responses of a corresponding number of the non-selected receive paths to the wireless signal (708). In some implementations, the wireless device 200 may be the receiving device D2 of FIG. 3B, may receive the wireless signal 310 from a transmitting device, and may determine the channel phase responses of the first and second antennas ANT1-ANT2 to the wireless signal 310.

The wireless device 200 may compare the first channel phase response with each of the number of other channel phase responses (710), and may determine a relative path delay and gain difference between the reference path and each of the non-selected receive paths based on the comparison (712).

The wireless device 200 may determine one or more sets of phase correction values based on the determined relative path delay and gain differences (714). In some implementations, the one or more phase correction values for the first receive chain may be determined relative to the channel phase response of the second receive chain. The wireless device 200 may store the phase correction values in a memory (such as the look-up table 236 of FIG. 2A). In some other implementations, the determined phase correction values may be stored in another suitable memory of the wireless device 200.

The wireless device 200 may adjust one or more of the other channel phase responses based on the one or more sets of phase correction values (716). In some implementations, the wireless device 200 may compensate for path delays and phase offsets of the reference path by applying a selected set of phase correction values to each of the one or more other channel phase responses.

The wireless device 200 may estimate angle of arrival information of the wireless signal based on the adjusted channel phase responses (718). Estimating angle information of the wireless signal based on the adjusted channel phase responses may increase the accuracy with which the wireless device 200 can estimate angle information (such as compared with conventional devices that do not adjust channel phase responses measured by the baseband processor), for example, because the adjusted channel phase responses account for differences in path delays and gains between the receive chains of the wireless device 200.

If an expected channel phase response is known, then a wireless device may determine the phase correction values without using a reference chain. In some implementations, the test setup 300 of FIG. 3A may be used to determine an expected channel phase response, for example, because the wireless signal 310 is received at the receiving device D2 at a known angle of arrival over a known channel. Thereafter, the wireless device may measure the channel phase response to a received wireless signal, and then compare the measured channel phase response with the expected channel phase response to determine the phase correction values.

While the operations 600 and 700 of FIG. 6A and FIG. 7, respectively, are described with respect to calibrating the wireless device 200 for estimating AoA information of a wireless signal, the operations 600 and 700 are equally applicable for calibrating the wireless device 200 for estimating AoD information of wireless signals transmitted from another wireless device.

In some other implementations, the operations 600 and 700 may be used to determine one or more phase correction values based on reception of a plurality of wireless signals (such as a plurality of frames or packets), which may result in more accurate phase correction values. For example, if a portion of the channel phase response (such as corresponding to some subcarriers) is an outlier from other portions of the channel phase response (such as corresponding to other subcarriers), then the phase correction values may be undesirably influenced by these “outlier” portions of the channel phase response. Determining phase correction values based on multiple received wireless signals (such as multiple packets) may allow errors attributed to a single wireless signal (such as a single packet) to be filtered or removed, for example, because different wireless signals or packets may have different sampling time offsets (such as when received by different antennas of a wireless device), which in turn may cause differences in the slopes of the measured channel phase responses.

In some implementations, the wireless device may compensate for these different sampling time offsets by using the absolute phase of each of its transceiver chains to determine the phase correction values. In some other implementations, the wireless device may compensate for these different sampling time offsets by using the differences in channel phase responses between antenna pairs (such as between antennas ANT1 and ANT2 of FIG. 2B, between antennas ANT1 and ANT3 of FIG. 2B, or between antennas ANT1 and ANT4 of FIG. 2B) to determine the phase correction values, for example, so that the absolute phase of each transceiver chain is not needed.

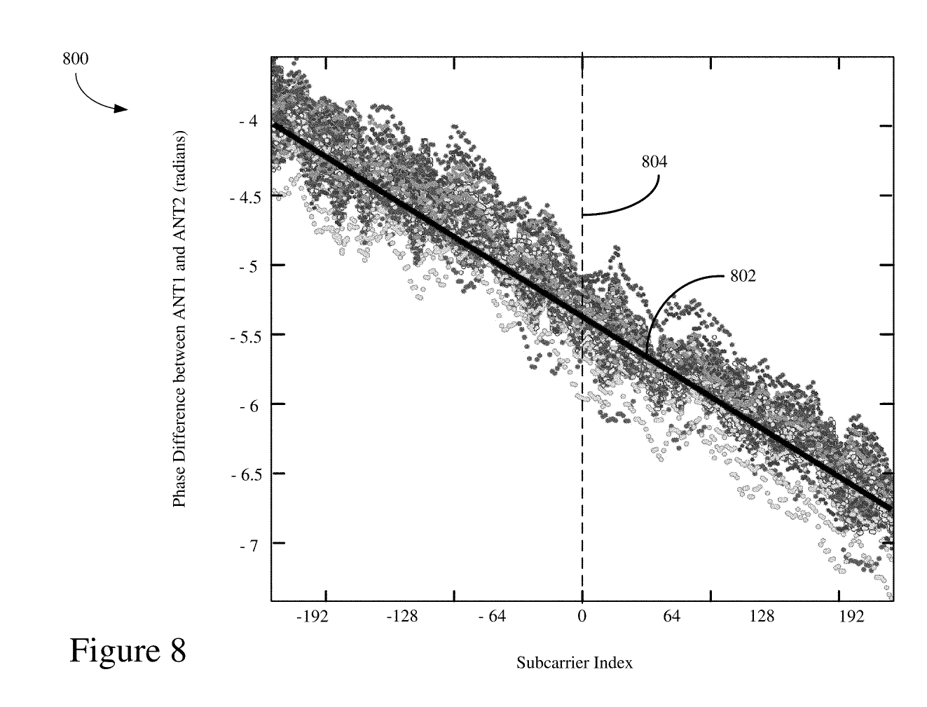

FIG. 8 shows a graph 800 of example differences in channel phase responses between receive chains of a wireless device. The channel phase responses are expressed in radians versus subcarrier index, and are represented by a plurality of dot plots. Each of the dot plots may indicate a measured phase difference between signal components of a corresponding wireless signal arriving at different antennas of a wireless device. In some implementations, each of the dots in the graph 800 may represent a measured phase difference at an associated subcarrier for a corresponding one of the wireless signals. The measured phase difference may vary between wireless signals. Referring also to FIGS. 2A and 2B, the receive chain associated with antenna ANT1 is selected as the reference chain, and the receive chains associated with antennas ANT2-ANT4 are designated as the non-selected (or non-reference) receive chains. In some implementations, the test setup 300 described with respect to FIG. 3A (or any other suitable anechoic chamber) may be used to determine phase correction values for the non-selected receive chains.

In some implementations, a statistical fit of the data may be used to determine a representative phase difference across the subcarrier index. For example, a line 802 in the graph 800 represents an example statistical fit for the data in the graph 800 using linear regression. In some other implementations, any suitable statistical fit may be used (such as a linear regression, multi-order regression, averaging, mean determination, and so on). If the test setup (such as the test setup 300 depicted in FIG. 3A) provides enough information to allow the wireless device 200 to obtain the expected phase difference between two receive chains across the subcarrier index, then the wireless device 200 may determine a phase correction value for the non-selected receive chain based on a comparison between the representative phase difference and the expected phase difference.

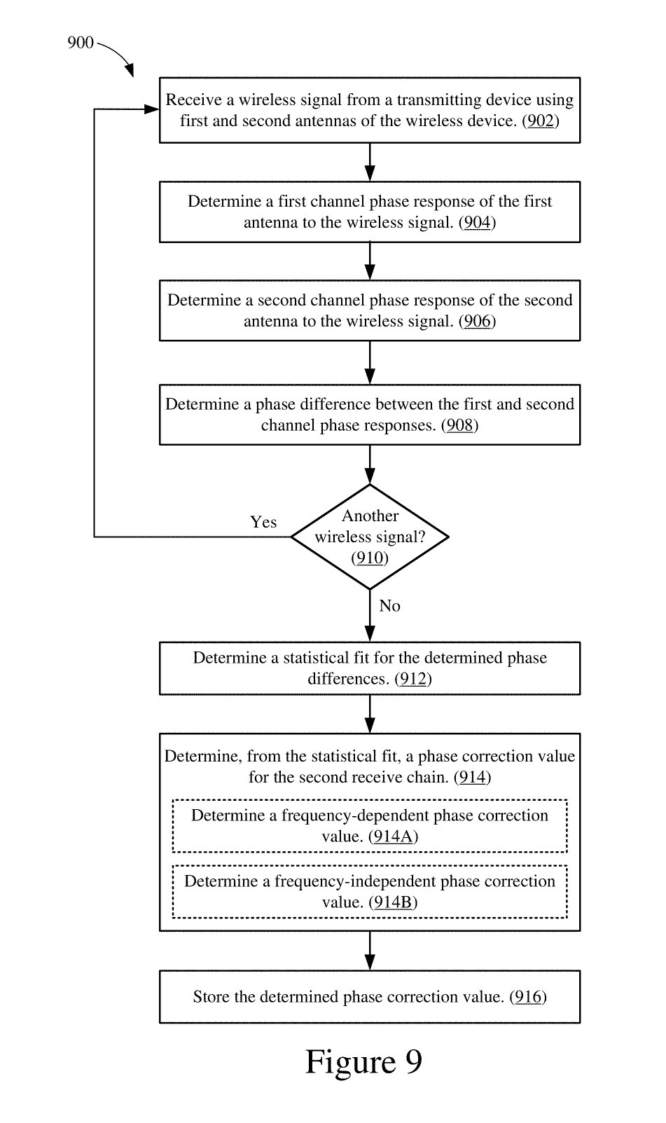

FIG. 9 shows an illustrative flow chart depicting an example operation 900 for determining one or more phase correction values based on a plurality of received wireless signals. Although the example operation 900 is described with respect to the wireless device 200 of FIGS. 2A and 2B, the example operation 900 may be performed by any suitable wireless device including, for example, one of the stations STA1-STA4 or the AP 110 of FIG. 1. In some implementations, the operation 900 may be repeated for different antenna gains of the receive chains of the wireless device 200. In some other implementations, the operation 900 may be repeated for different receive chains to determine phase correction values for all of the non-selected receive chains of the wireless device 200. Further, although described in the context of using two antennas (such as the first and second antennas ANT1-ANT2) of the wireless device 200 to receive wireless signals, the example operation 900 is equally applicable when the wireless device 200 uses more than two antennas to receive wireless signals (such as when using four antennas ANT1-ANT4 of the wireless device 200 to receive wireless signals).

A first receive chain of the wireless device 200 is selected as the reference chain, and a second receive chain of the wireless device 200 is designated as the non-selected receive chain. Referring also to FIG. 2B, the first receive chain is provided within transceiver chain 211A and is coupled to the first antenna ANT1 via the first antenna cable 230A, and the second receive chain is provided within transceiver chain 211B and is coupled to the second antenna ANT2 via the second antenna cable 230B. The first receive chain and the antenna cable 230A may be referred to as the first receive path, and the second receive chain and the antenna cable 230B may be referred to as the second receive path.

The wireless device 200 receives a wireless signal from a transmitting device using its first and second antennas ANT1-ANT2 (902). Signal components of the wireless signal received by the first antenna ANT1 are provided to the first receive chain via the first antenna cable 230A, and signal components of the wireless signal received by the second antenna ANT2 are provided to the second receive chain via the second antenna cable 230B.

The wireless device 200 determines a first channel phase response of the first antenna ANT1 to the wireless signal at (904), and determines a second channel phase response of the second antenna ANT2 to the wireless signal (906). The wireless device 200 determines a phase difference between the first and second channel phase responses (908).

If there is another wireless signal to be received, as tested at 910, then the example operation 900 proceeds to 902, and the wireless device 200 determines the phase difference between the first and second channel phase responses based on the other wireless signal. Conversely, if there is not another wireless signal to be received, as tested at 910, then the wireless device 200 determines a statistical fit for the determined phase differences (912). For the example operation 900, a linear regression is used to determine the statistical fit, which generates a data set that may be graphed as a straight line across the subcarrier index (with the line having a slope and y-intercept). In some other implementations, other suitable statistical fits may be used (such as a linear regression, multi-order regression, averaging, mean determination, and so on).

Referring also to FIG. 8, the example graph 800 shows a plurality of phase differences that may be determined between the first receive chain and the second receive chain of the wireless device 200. The example graph 800 also shows the statistical fit as the line 802, which includes a slope indicating the linear change in phase difference and a y-intercept indicating the phase difference of the line 802 when crossing the dashed lined 804 (such as corresponding to subcarrier 0).

Referring again to FIG. 9, the wireless device 200 determines, from the statistical fit, a phase correction value for the second receive chain (914). If enough information about the test setup 300 is known, then the expected phase difference between the first receive chain and the second receive chain may be known. For example, the expected phase difference may be graphed as a line with its own slope and y-intercept. In some implementations, the wireless device 200 may determine a frequency-dependent phase correction value (914A) and a frequency-independent phase correction value (914B). The frequency-dependent phase correction value may be used to compensate for differences in path delays between the first and second receive chains, and the frequency-independent phase correction value may be used to compensate for differences in phase offsets between the first and second receive chains. In some implementations, the frequency-dependent phase correction value may be used to adjust the slope of the line 802 of FIG. 8 to match the expected slope, and the frequency-independent phase correction value may be used to adjust the y-intercept point of the line 802 of FIG. 8 to the expected y-intercept point.

In some implementations, the wireless device 200 may store the determined phase correction values in a memory (916). In some implementations, the determined phase correction values may be stored in the look-up table 236 of FIG. 2A. In some other implementations, the determined phase correction values may be stored in another suitable memory of the wireless device 200.

In some implementations, the phase correction values may be determined in a factory environment (such as at time of device manufacture). For example, calibration of a wireless device for determining angle information may be performed at different stages of the manufacturing process (such as at a chip level, at a board level (thus capturing off-chip component effects), or at a finished product level (capturing antenna and antenna cabling effects as well as off-chip component effects)). In some other implementations, the manufacturer may store, in each of a plurality of wireless devices, the phase correction values determined by or for another similar device (such as same stock keeping unit (SKU)/design). The phase correction values may be determined at a batch level (of the chip, board, or device) or at a model or design level. For example, a smartphone manufacturer may use one test smartphone to determine the phase correction values, and may store the phase correction values determined by the test smartphone on a plurality of other smartphone having the same design or components as the test smartphone. In this manner, the manufacturer may test only a subset of the devices to be sent to end users, for example, by assuming that the path delay and smartphone component contributions to phase offsets are approximately the same for all devices of the same design.

In some other implementations, a wireless device may determine (or update) the phase correction values during normal use. In some implementations, the wireless device may include feedback or other loopback paths in order to determine (or update) the phase correction values. In this manner, the wireless device may be able to adjust the phase correction values to counteract the effects of device age and temperature variations upon angle information estimates. Because some components of a wireless device may not require calibration adjustments (such as if the component is not significantly affected by aging or temperature), the wireless device may adjust the phase correction values for only a subset of components that affect phase offsets for determining angle information.

In some implementations, a wireless device may store a number of phase correction values in memory, and thereafter retrieve one or more of the phase correction values from the memory when estimating AoA information of received wireless signals. The phase correction values may be indexed by transceiver chain, by gain levels, or by any other suitable indexing scheme.

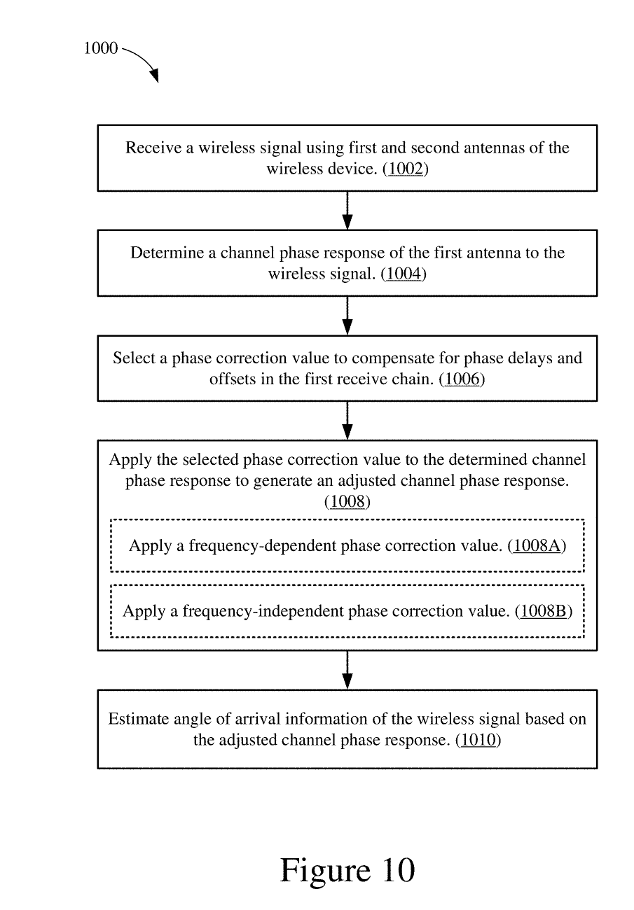

FIG. 10 shows an illustrative flow chart depicting an example operation 1000 for estimating angle of arrival information of a wireless signal. For purposes of discussion herein, the example operation 1000 is described with respect to the wireless device 200 of FIGS. 2A and 2B. However, it is to be understood that the example operation 1000 may be performed by any suitable wireless device including, for example, one of the stations STA1-STA4 or the AP 110 of FIG. 1. Further, although described in the context of using two antennas (such as the first and second antennas ANT1-ANT2) of the wireless device 200 to receive wireless signals, the example operation 1000 is equally applicable when the wireless device 200 uses more than two antennas to receive wireless signals (such as when using four antennas ANT1-ANT4 of the wireless device 200 to receive wireless signals).

The wireless device 200 receives a wireless signal from a transmitting device using its first and second antennas ANT1-ANT2 (1002). Signal components of the wireless signal received by the first antenna ANT1 may be provided to the first receive chain via the first antenna cable 230A, and signal components of the wireless signal received by the second antenna ANT2 may be provided to the second receive chain via the second antenna cable 230B. The first receive chain and the first antenna cable 230A may be referred to as the first receive path, and the second receive chain and the second antenna cable 230B may be referred to as the second receive path.

The wireless device 200 determines a channel phase response of the first antenna ANT1 to the wireless signal (1004), and selects a phase correction value to compensate for phase delays and offsets in the first receive chain (1006). In some implementations, the wireless device 200 may select the phase correction value from the look-up table 236 of FIG. 2A. In some implementations, the wireless device 200 may select the phase correction value based on a gain setting of the first receive chain. In some other implementations, the wireless device 200 may select the phase correction value based on an identification of the first receive chain.

The wireless device 200 applies the selected phase correction value to the determined channel phase response to generate an adjusted channel phase response (1008). In some implementations, the wireless device 200 may determine a frequency-dependent phase correction value (1008A), and may determine a frequency-independent phase correction value (1008B). The frequency-dependent phase correction value may be used to compensate for differences in path delays between the receive chains of the wireless device 200, and the frequency-independent phase correction value may be used to compensate for differences in phase offsets between the receive chains of the wireless device 200.

The wireless device 200 may estimate angle of arrival information of the wireless signal based on the adjusted channel phase response (1010). Because the adjusted channel phase response compensates for phase offsets associated with the first receive path of the wireless device 200, using the adjusted channel phase response to estimate angle of arrival information of the wireless signal may increase the accuracy with which the wireless device 200 can estimate angle of arrival information (such as compared with conventional wireless devices which do not adjust channel phase responses measured by the baseband processor).

A wireless device also may calculate angle of departure information of a wireless signal transmitted from a transmitting device using phase correction values. Because differences in path delays and gains between the transmit chains of the transmitting device may cause phase offsets in wireless signals transmitted from the transmitting device (which in turn may affect angle of departure information estimated by the receiving device), one or more phase correction values may be used to compensate for such differences between the transmit chains of the transmitting device. In some implementations, the transmitting device may determine one or more phase correction values for its transmit chains in a manner similar to the receiving device determining phase correction values for its receive chains. The transmitting device may store its phase correction values in memory, and may transmit (or otherwise provide) these phase correction values to the receiving device. In some implementations, the transmitting device may advertise its phase correction values (such as over the air, for example, in broadcast frames) to one or more receiving devices. The one or more receiving devices may use the phase correction values provided by the transmitting device when estimating AoD information of wireless signals transmitted from the transmitting device.

In some other implementations, the transmitting device may apply phase correction values on signals (such as internally on its transmit chains) prior to transmitting the signals to other wireless devices via the wireless medium, thereby allowing a receiving device to directly estimate AoD information based on the transmitted signal waveform (such as without using additional signaling or protocols).

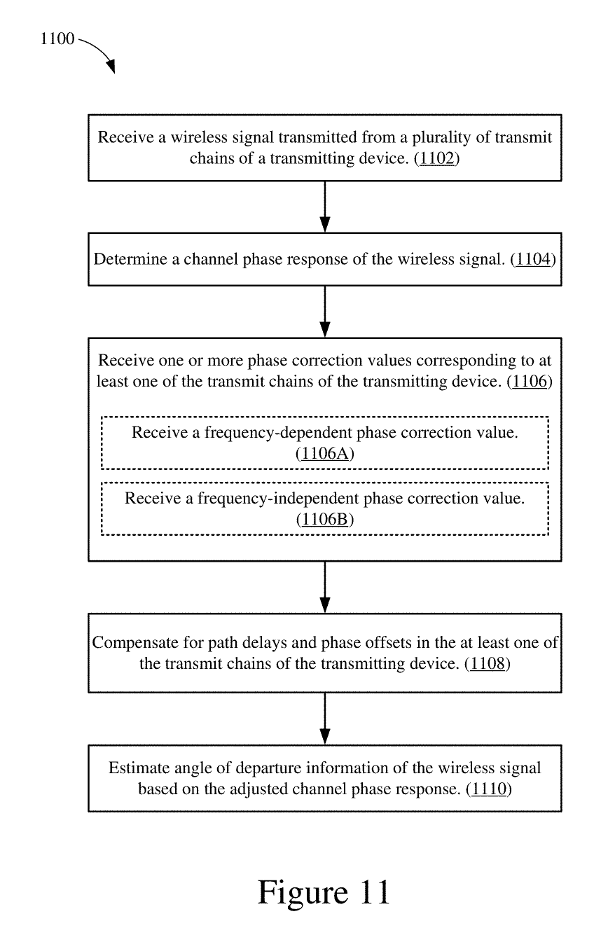

FIG. 11 shows an illustrative flow chart depicting an example operation 1100 for estimating angle of departure information of a wireless signal. Although the example operation 1100 is described with respect to the wireless device 200 of FIGS. 2A and 2B, the example operation 1100 may be performed by any suitable wireless device including, for example, one of the stations STA1-STA4 or the AP 110 of FIG. 1. In some implementations, the operation 1100 may be repeated for different gains of the receive chains of the wireless device 200. In some other implementations, the operation 1100 may be repeated using various receive chains as the reference receive chain. Further, although described in the context of using two antennas (such as the first and second antennas ANT1-ANT2) of the wireless device 200 to receive wireless signals, the example operation 1100 is equally applicable when the wireless device 200 uses more than two antennas to receive wireless signals (such as when using four antennas ANT1-ANT4 of the wireless device 200 to receive wireless signals).

The wireless device 200 receives a wireless signal transmitted from a plurality of transmit chains of a transmitting device (1102), and determines a channel phase response to the received wireless signal (1104). In some implementations, the channel phase response versus the subcarrier index may be graphed as a straight line with a slope and y-intercept point, for example, as described with respect to FIG. 4.

The wireless device 200 may receive, from the transmitting device, one or more phase correction values for each of a number of the transmit chains of the transmitting device (1106). The phase correction values may be used adjust the slope and y-intercept point that corresponds to the phase offsets caused by front-end components of the transmit chain of the transmitting device. The phase correction value may be received in any suitable manner including, for example, in an Over-The-Air (OTA) transmission, a broadcast frame, an information element (IE) embedded within a frame, a vendor-specific information element (VSIE) embedded within a frame, and so on. In some implementations, the wireless device 200 may receive a frequency-dependent phase correction value (1106A), and may receive a frequency-independent phase correction value (1106B). The frequency-dependent phase correction value may be used to compensate for differences in path delays between transmit chains of the transmitting device, and the frequency-independent phase correction value may be used to compensate for differences in phase offsets between the transmit chains of the transmitting device.

The wireless device 200 may compensate for path delays and phase offsets of the at least one of the transmit chains of the transmitting device (1108). In some implementations, the wireless device 200 may compensate for path delays and phase offsets of the at least one of the transmit chains of the transmitting device by adjusting the determined channel phase response using the one or more phase correction values received from the transmitting device.

The wireless device 200 may estimate angle of departure information of the wireless signal based on the adjusted channel phase response (1110). Because the adjusted channel phase response compensates for phase offsets associated with the at least one of the transmit chains of the transmitting device, using the adjusted channel phase response to estimate angle of departure information of the wireless signal may increase the accuracy with which the wireless device 200 can estimate angle of departure information (such as compared with conventional techniques that do not adjust channel phase responses measured by the baseband processor).

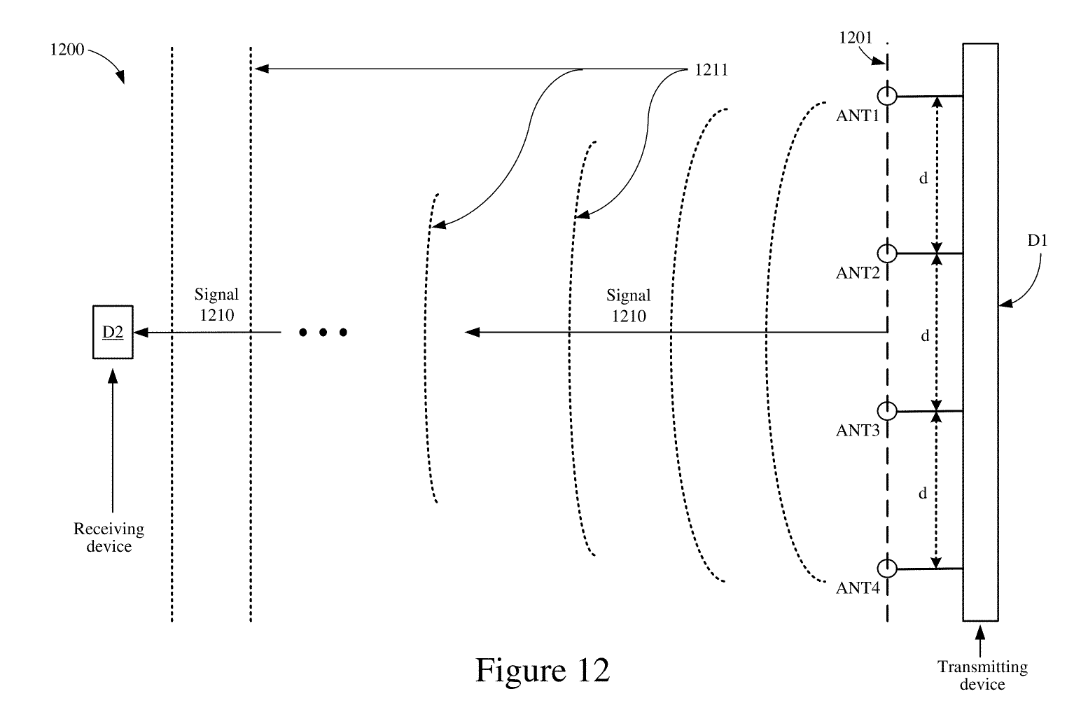

FIG. 12 shows an example test setup 1200 for calibrating a transmitting device. The test setup 1200 depicts a transmitting device D1 transmitting a wireless signal 1210 to a receiving device D2. In some implementations, the test setup 1200 may be an anechoic chamber, for example, so that the receiving device D2 does not receive reflections of wireless signal 1210 (such as being reflected off of walls or other objects). In this manner, the receiving device D2 may receive line of sight (LOS) signal components of the wireless signal 1210. In some other implementations, the receiving device D2 may receive both non-line of sight (NLOS) signal components and LOS signal components of wireless signal 1210, and may filter out or otherwise remove the NLOS signal components, for example, so that the LOS signal components are used to estimate angle information of the wireless signal 1210 transmitted from the transmitting device D1.

The transmitting device D1 is shown to include four antennas ANT1-ANT4 oriented along a straight line 1201 and separated from each other by a distance d. The receiving device D2 may include a single antenna (not shown for simplicity). In some implementations, the transmitting device D1 may be positioned a sufficient distance from the receiving device D2 so that the wireless signal 1210 reaches the receiving device D2 in the approximate form of a plane wave (as indicated by plane waves 1211). The transmitting device D1 and the receiving device D2 also may have known positions and orientations relative to each other so that components of the wireless signal 1210 transmitted from each of the antennas ANT1-ANT4 of the transmitting device D1 arrive at the antenna (not shown for simplicity) of the receiving device D2 at the same time (or at least at substantially similar times). In some implementations, components of the wireless signal 1210 transmitted from the four antennas ANT1-ANT4 of the transmitting device D1 may be orthogonal to each other (such as by using code division, time division, frequency division, or any combination thereof). In this manner, the wireless signal 1210 may be transmitted from the transmitting device D1 to the receiving device D2 at a known angle (such as an AoD=0 degrees).

The receiving device D2 may determine channel phase responses based on signal components of the wireless signal 1210 transmitted from each of the four antennas ANT1-ANT4 of the transmitting device D1. In some implementations, the receiving device D2 may select one of the four antennas ANT1-ANT4 (such as antenna ANT1) of the transmitting device D1 as a reference antenna, and may determine phase correction values for the three other antennas (such as antennas ANT2-ANT4) of the transmitting device D1. The receiving device D2 may provide the phase correction values to the transmitting device D1. In some implementations, the phase correction values may include frequency-dependent phase correction values and frequency-independent phase correction values. The transmitting device D1 may store the phase correction values provided by the receiving device D2, and may apply these phase correction values to its transmit chains prior to subsequent transmissions of wireless signals from which the receiving device D2 may estimate angle information. In this manner, the transmitting device D1 may be calibrated to compensate for path delays and phase offsets between its transmit chains, which in turn may increase the accuracy with which other wireless devices (such as the receiving device D2) can estimate AoD information of wireless signals transmitted from the transmitting device D1.

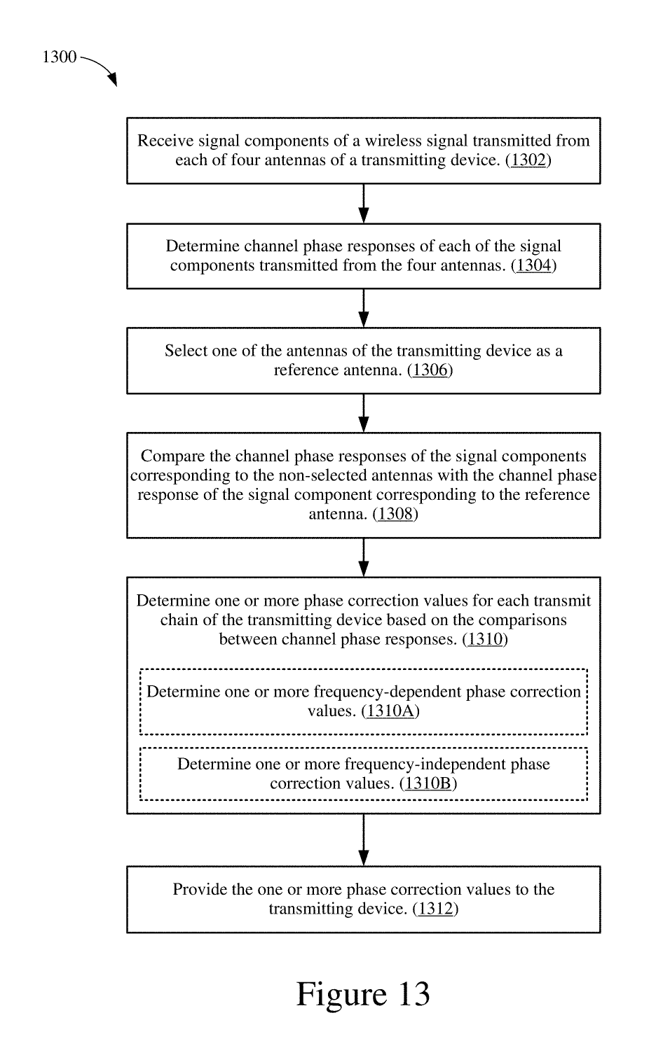

FIG. 13 shows an illustrative flow chart depicting an example operation 1300 for calibrating a transmitting device. Although the example operation 1300 is described with respect to the transmitting device D1 and the receiving device D2 of FIG. 12, the example operation 1300 may be performed by any suitable wireless devices including, for example, the stations STA1-STA4 of FIG. 1, the AP 110 of FIG. 1, or the wireless device 200 of FIG. 2A. In some implementations, the operation 1300 may be repeated for different gains of the transmit chains of the transmitting device D1. Further, although described in the context of using four antennas to transmit wireless signals, the example operation 1300 is equally applicable when using other numbers of antennas to transmit wireless signals.

The receiving device D2 receives signal components of the wireless signal transmitted from each of the four antennas ANT1-ANT4 of the transmitting device D1 (1302). In some implementations, the signal components transmitted from the four antennas ANT1-ANT4 of the transmitting device D1 are orthogonal to each other. The receiving device D2 may determine a channel phase response of each of the signal components transmitted from the four antennas ANT1-ANT4 of the transmitting device D1 (1304). In some implementations, the receiving device D2 may utilize the orthogonality between the signal components transmitted from the transmitting device D1 to determine the channel phase responses of the signal components associated with each of the four antennas ANT1-ANT4 of the transmitting device D1.

The receiving device D2 selects one of the four antennas ANT1-ANT4 of the transmitting device D1 as a reference antenna (1306), and compares the channel phase responses of the signal components corresponding to the non-selected antennas with the channel phase response of the signal component corresponding to the reference antenna (1308). The receiving device D2 determines one or more phase correction values for each of the transmit chains of the transmitting device D1 based on the comparisons between the channel phase responses (1310). In some implementations, the receiving device D2 may determine one or more frequency-dependent phase correction values (1310A), and may determine one or more frequency-independent phase correction values (1310B). In some implementations, the frequency-dependent phase correction values may be used to compensate for differences between the path delays of the transmit chains of the transmitting device D1 and an expected path delay, and the frequency-independent phase correction values may be used to compensate for differences between the phase offsets of the transmit chains of the transmitting device D1 and an expected phase offset.

The receiving device D2 may provide (such as by transmitting) the one or more determined phase correction values to the transmitting device D1 (1312). Thereafter, the transmitting device D1 may store the one or more determined phase correction values. The transmitting device D1 may apply the one or more phase correction values to its transmit chains prior to the subsequent transmission of wireless signals to be used by other wireless devices for estimating angle information.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method of compensating for differences in path delays and gains between receive paths of a wireless device, comprising:
receiving a first wireless signal using first and second receive paths of the wireless device, the first receive path including a first antenna cable and a first receive chain, the second receive path including a second antenna cable and a second receive chain;
determining a first channel phase response of the first receive path to the first wireless signal;
determining a second channel phase response of the second receive path to the first wireless signal;
comparing the first and second channel phase responses with an expected channel phase response;
determining, for each of the first receive path and the second receive path, one or more phase correction values based on the comparison; and
adjusting the first and second channel phase responses based on the phase correction values.

2. The method of claim 1, wherein the adjusted first and second channel phase responses compensate for at least one of:
differences in path delays between the first antenna cable and the second antenna cable;
differences in path delays between the first receive chain and the second receive chain; and
differences in gain between the first receive chain and the second receive chain.

3. The method of claim 1, further comprising:
estimating angle of arrival information of the first wireless signal based on the adjusted channel phase responses.

4. The method of claim 1, wherein at least one of the phase correction values comprises:
a frequency-dependent phase correction value indicating a difference in path delays between the first receive path and the second receive path; and
a frequency-independent phase correction value indicating a difference in phase offsets between the first receive path and the second receive path.

5. The method of claim 1, further comprising:
storing the phase correction values in a memory of the wireless device.

6. The method of claim 5, further comprising:
receiving a second wireless signal using the first and second receive paths;
determining a channel phase response to the second wireless signal;
retrieving a selected one of the phase correction values from the memory;
adjusting the channel phase response to the second wireless signal based on the selected phase correction value; and
estimating angle of arrival information of the second wireless signal based on the adjusted channel phase response to the second wireless signal.

7. The method of claim 6, wherein the selected phase correction value is based at least in part on a gain setting of one or both of the first and second receive paths.

8. The method of claim 1, wherein the expected channel phase response is determined in a test setup with a transmitting device having a known position and a known orientation relative to the wireless device.

9. The method of claim 8, wherein the test setup comprises an anechoic chamber.

10. The method of claim 1, wherein the first wireless signal is transmitted by a smartphone.

11. The method of claim 10, wherein the smartphone is positioned, by a user, at a known orientation relative to the wireless device.

12. The method of claim 11, further comprising:
executing an application on the smartphone to determine the known orientation.

13. An apparatus, comprising:
a first receive path including a first antenna cable and a first receive chain;
a second receive path including a second antenna cable and a second receive chain;
one or more processors; and
a memory comprising instructions that, when executed by the one or more processors, cause the apparatus to:
receive a first wireless signal using the first and second receive paths;
determine a first channel phase response of the first receive path to the first wireless signal;
determine a second channel phase response of the second receive path to the first wireless signal;
compare the first and second channel phase responses with an expected channel phase response;
determine, for each of the first receive path and the second receive path, one or more phase correction values based on the comparison; and
adjust the first and second channel phase responses based on the phase correction values.

14. The apparatus of claim 13, wherein the adjusted first and second channel phase responses compensate for at least one of:
differences in path delays between the first antenna cable and the second antenna cable;
differences in path delays between the first receive chain and the second receive chain; and
differences in gain between the first receive chain and the second receive chain.

15. The apparatus of claim 13, wherein execution of the instructions further causes the apparatus to:
estimate angle of arrival information of the first wireless signal based on the adjusted channel phase responses.

16. The apparatus of claim 13, wherein at least one of the phase correction values comprises:
a frequency-dependent phase correction value indicating a difference in path delays between the first receive path and the second receive path; and
a frequency-independent phase correction value indicating a difference in phase offsets between the first receive path and the second receive path.

17. The apparatus of claim 13, wherein execution of the instructions further causes the apparatus to:
store the phase correction values in a memory of the apparatus.

18. The apparatus of claim 17, wherein execution of the instructions further causes the apparatus to:
receive a second wireless signal using the first and second receive paths;
determine a channel phase response to the second wireless signal;
retrieve a selected one of the phase correction values from the memory;
adjust the channel phase response to the second wireless signal based on the selected phase correction value; and
estimate angle of arrival information of the second wireless signal based on the adjusted channel phase response to the second wireless signal.

19. The apparatus of claim 18, wherein the selected phase correction value is based at least in part on a gain setting of one or both of the first and second receive paths.

20. The apparatus of claim 13, wherein the expected channel phase response is determined in a test setup with a transmitting device having a known position and a known orientation relative to the apparatus.

21. The apparatus of claim 20, wherein the test setup comprises an anechoic chamber.

22. A method of compensating for differences in path delays and gains between receive paths of a wireless device, comprising:
receiving a wireless signal using a plurality of receive paths of the wireless device, each of the receive paths including an antenna cable and a receive chain;
selecting one of the plurality of receive paths as a reference path;
determining a first channel phase response of the reference path to the wireless signal;
determining a number of other channel phase responses of a number of corresponding non-selected receive paths to the wireless signal;
comparing the first channel phase response with each of the number of other channel phase responses;
determining a relative path delay and gain difference between the reference path and each of the number of non-selected receive paths based on the comparison;
determining one or more sets of phase correction values based on the determined relative path delay and gain differences; and
adjusting one or more of the other channel phase responses based on the one or more sets of phase correction values.

23. The method of claim 22, wherein each of the one or more adjusted channel phase responses compensates for differences in path delays and gains between the reference path and a corresponding one of the non-selected receive paths.

24. The method of claim 22, further comprising:
estimating angle of arrival information of the wireless signal based on the adjusted channel phase responses.

25. The method of claim 22, wherein at least one of the phase correction values comprises:
a frequency-dependent phase correction value indicating a difference in path delays between the reference path and a respective one of the non-selected receive paths; and
a frequency-independent phase correction value indicating a difference in phase offsets between the reference path and the respective one of the non-selected receive paths.

26. The method of claim 25, wherein the wireless signal is transmitted by smartphone.

27. An apparatus, comprising:
a plurality of receive paths each including an antenna cable and a receive chain;
one or more processors; and
a memory comprising instructions that, when executed by the one or more processors, cause the apparatus to:
receive a wireless signal using the plurality of receive paths;
select one of the plurality of receive paths as a reference path;
determine a first channel phase response of the reference path to the wireless signal;
determine a number of other channel phase responses of a number of corresponding non-selected receive paths to the wireless signal;
compare the first channel phase response with each of the number of other channel phase responses;
determine a relative path delay and gain difference between the reference path and each of the number of non-selected receive paths based on the comparison;
determine one or more sets of phase correction values based on the determined relative path delay and gain differences; and
adjust one or more of the other channel phase responses based on the one or more sets of phase correction values.

28. The apparatus of claim 27, wherein each of the one or more adjusted channel phase responses compensates for differences in path delays and gains between the reference path and a corresponding one of the non-selected receive paths.

29. The apparatus of claim 27, wherein execution of the instructions further causes the apparatus to:
estimate angle of arrival information of the wireless signal based on the adjusted channel phase responses.

30. The apparatus of claim 27, wherein at least one of the phase correction values comprises:
a frequency-dependent phase correction value indicating a difference in path delays between the reference path and a respective one of the non-selected receive paths; and
a frequency-independent phase correction value indicating a difference in phase offsets between the reference path and the respective one of the non-selected receive paths.
